(19) United States
(12) Patent Application Publication
(10) Pub. No.: US 2024/0389328 A1
(43) Pub. Date: Nov. 21, 2024

(54) MEMORY DEVICE

(71) Applicant: Kioxia Corporation, Tokyo (JP)

(72) Inventors: Kazuma HAYASHI, Yokkaichi (JP); Shinya ARAI, Yokohama (JP); Keisuke SUDA, Yokkaichi (JP); Masakazu SAWANO, Mie (JP)

(73) Assignee: Kioxia Corporation, Tokyo (JP)

(21) Appl. No.: 18/664,450

(22) Filed: May 15, 2024

(30) Foreign Application Priority Data
May 15, 2023 (JP) 2023-080287

(51) Int. Cl. H10B 43/35; H01L 23/528; H10B 43/10

(52) U.S. Cl. CPC H10B 43/35; H01L 23/5283; H10B 43/10

(57) ABSTRACT

In general, according to one embodiment, a semiconductor device includes: a plurality of first conductor layers arranged apart from each other in a first direction; a memory pillar extending in the first direction and including a portion crossing a respective one of the first conductor layers, the portion functioning as a memory cell; and a first conductor member surrounding, in a first direction perspective, the first conductor layers and the memory pillar, the first conductor member crossing an extension of at least one of the first conductor layers. The first conductor member includes a first direction first end having, in the first direction perspective, a dent and rise profile in a longitudinal direction of the first conductor member.

### CROSS-REFERENCE TO RELATED APPLICATIONS

This application is based upon and claims the benefit of priority from Japanese Patent Application No. 2023-080287, filed May 15, 2023, the entire contents of which are incorporated herein by reference.

### FIELD

Embodiments described herein relate generally to a memory device.

### BACKGROUND

A NAND flash memory is known as a memory device capable of storing data in a non-volatile manner. Such a memory device as represented by a NAND flash memory adopts a three-dimensional memory structure for enhanced integration and increased capacity.

### BRIEF DESCRIPTION OF THE DRAWINGS

FIG. 1 is a block diagram showing an exemplary configuration of a memory system which includes a memory device according to a first embodiment.

FIG. 2 is a circuit diagram showing an exemplary circuit configuration of a memory cell array fabricated in the memory device according to the first embodiment.

FIG. 3 is a perspective view generally showing a bonded structure of the memory device according to the first embodiment.

FIG. 4 is a plan view showing an exemplary planar layout of the memory device according to the first embodiment.

FIG. 5 is a sectional view taken along the line V-V in FIG. 4 and shows an exemplary sectional structure of the memory device according to the first embodiment.

FIG. 6 is a plan view showing an exemplary planar layout of members arranged in a core region, and also wall structures arranged in a wall region and an outer peripheral region, in the memory device according to the first embodiment.

FIG. 7 is a plan view of the area VII in FIG. 6 and shows an exemplary planar layout of a block region in the memory device according to the first embodiment.

FIG. 8 is a sectional view taken along the line VIII-VIII in FIG. 7 and shows an exemplary sectional structure of the block region in the memory device according to the first embodiment.

FIG. 9 is a sectional view taken along the line IX-IX in FIG. 7 and shows an exemplary sectional structure of the block region in the memory device according to the first embodiment.

FIG. 10 is a sectional view taken along the line X-X in FIG. 8 and shows an exemplary sectional structure of a memory pillar in the memory device according to the first embodiment.

FIG. 11 is a plan view of the area XI in FIG. 6 and shows an exemplary planar layout of the wall region and the outer peripheral region in the memory device according to the first embodiment.

FIG. 12 is a sectional view taken along the line XII-XII in FIG. 11 and shows an exemplary sectional structure of the wall region in the memory device according to the first embodiment.

FIG. 13 is a sectional view taken along the line XIII-XIII in FIG. 11 and shows an exemplary sectional structure of the wall region in the memory device according to the first embodiment.

FIG. 14 is a sectional view taken along the line XIV-XIV in FIG. 11 and shows an exemplary sectional structure of the wall region in the memory device according to the first embodiment.

FIG. 15 is a sectional view showing an exemplary sectional structure of bonding pads in the memory device according to the first embodiment.

FIG. 16 is a sectional view showing an exemplary sectional structure of the memory device according to the first embodiment in a state during the manufacture.

FIG. 17 is a sectional view showing an exemplary sectional structure of the memory device according to the first embodiment in a state during the manufacture.

FIG. 18 is a sectional view showing an exemplary sectional structure of the memory device according to the first embodiment in a state during the manufacture.

FIG. 19 is a sectional view showing an exemplary sectional structure of the memory device according to the first embodiment in a state during the manufacture.

FIG. 20 is a sectional view showing an exemplary sectional structure of the memory device according to the first embodiment in a state during the manufacture.

FIG. 21 is a sectional view showing an exemplary sectional structure of the memory device according to the first embodiment in a state during the manufacture.

FIG. 22 is a sectional view showing an exemplary sectional structure of the memory device according to the first embodiment in a state during the manufacture.

FIG. 23 is a sectional view showing an exemplary sectional structure of the memory device according to the first embodiment in a state during the manufacture.

FIG. 24 is a sectional view showing an exemplary sectional structure of the memory device according to the first embodiment in a state during the manufacture.

FIG. 25 is a sectional view showing an exemplary sectional structure of the memory device according to the first embodiment in a state during the manufacture.

FIG. 26 is a sectional view showing an exemplary sectional structure of the memory device according to the first embodiment in a state during the manufacture.

FIG. 27 is a plan view showing an exemplary planar layout of a wall region and an outer peripheral region in a memory device according to a second embodiment.

FIG. 28 is a sectional view taken along the line XXVIII-XXVIII in FIG. 27 and shows an exemplary sectional structure of the wall region in the memory device according to the second embodiment.

FIG. 29 is a sectional view taken along the line XXIX-XXIX in FIG. 27 and shows an exemplary sectional structure of the wall region in the memory device according to the second embodiment.

FIG. 30 is a sectional view taken along the line XXX-XXX in FIG. 27 and shows an exemplary sectional structure of the wall region in the memory device according to the second embodiment.

FIG. 31 is a plan view showing an exemplary planar layout of a wall region and an outer peripheral region in a memory device according to a first modification.

FIG. 32 is a sectional view taken along the line XXXII-XXXII in FIG. 31 and shows an exemplary sectional structure of the wall region in the memory device according to the first modification.

FIG. 33 is a sectional view taken along the line XXXIII-XXXIII in FIG. 31 and shows an exemplary sectional structure of the wall region in the memory device according to the first modification.

FIG. 34 is a plan view showing a first exemplary planar layout of a wall region and an outer peripheral region in a memory device according to a second modification.

FIG. 35 is a plan view showing a second exemplary planar layout of the wall region and the outer peripheral region in the memory device according to the second modification.

FIG. 36 is a sectional view showing an exemplary sectional structure of a memory device according to a third modification.

### DETAILED DESCRIPTION

In general, according to one embodiment, a memory device includes: a plurality of first conductor layers arranged apart from each other in a first direction; a memory pillar extending in the first direction and including a portion crossing a respective one of the first conductor layers, the portion functioning as a memory cell; and a first conductor member surrounding, in a first direction perspective, the first conductor layers and the memory pillar, the first conductor member crossing an extension of at least one of the first conductor layers. The first conductor member includes a first direction first end having, in the first direction perspective, a dent and rise profile in a longitudinal direction of the first conductor member.

Embodiments will be described with reference to the drawings. The dimensions, scales, etc., used in the drawings are not binding on actual products.

The description will use the same reference signs for the elements or components having the same or substantially the same functions and configurations. To distinguish between elements having the same or substantially the same configurations, the description may add different characters or numerals after their respective reference signs.

### 1. First Embodiment

### 1.1 Configurations

### 1.1.1 Configuration of Memory System

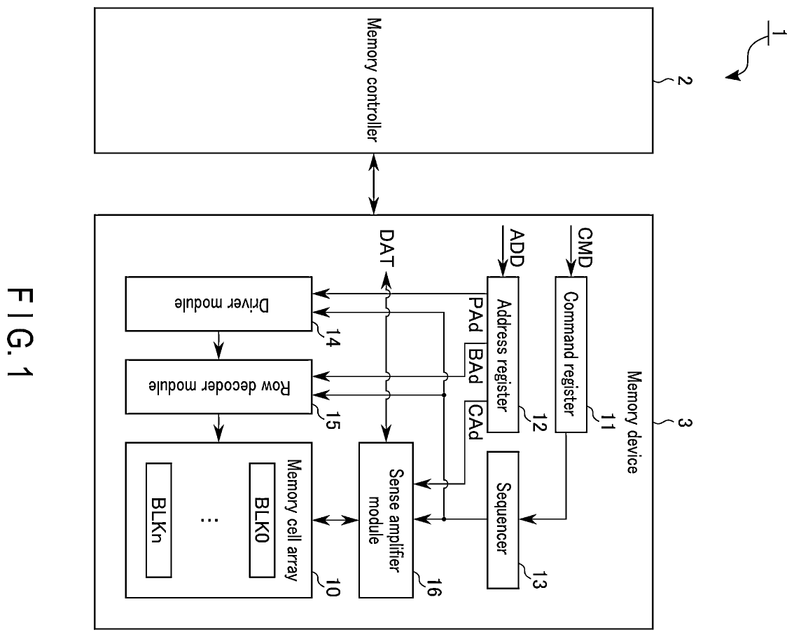

FIG. 1 is a block diagram showing an exemplary configuration of a memory system which includes a memory device according to a first embodiment. The memory system 1 is a storage device adapted for connection with an external host (not shown in the figure). Examples of the memory system 1 include a memory card such as an SD™ card, a universal flash storage (UFS), and a solid state drive (SSD). The memory system 1 includes a memory controller 2 and a memory device 3.

The memory controller 2 is constituted by, for example, an integrated circuit such as a system-on-a-chip (SoC). The memory controller 2 controls the memory device 3 as requested by the host. More specifically, and for example, the memory controller 2 writes data designated by the host for a write operation into the memory device 3. Also, the memory controller 2 reads data designated by the host for a read operation from the memory device 3 and sends it to the host.

The memory device 3 is a non-volatile memory. Examples of the memory device 3 include a NAND flash memory. The memory device 3 stores data in a non-volatile manner.

Communications between the memory controller 2 and the memory device 3 comply with, for example, a single data rate (SDR) interface, a toggle double data rate (DDR) interface, an open NAND flash interface (ONFI), etc.

### 1.1.2 Configuration of Memory Device

Still referring to the block diagram in FIG. 1, an internal configuration of the memory device according to the first embodiment will be described. The memory device 3 includes, for example, a memory cell array 10, a command register 11, an address register 12, a sequencer 13, a driver module 14, a row decoder module 15, and a sense amplifier module 16.

The memory cell array 10 includes multiple blocks BLK0 to BLKn, where n is an integer equal to or greater than 1. The number of blocks BLK in the memory cell array 10 may be any number including 1. Each block BLK is a set of multiple memory cells. In one example, each block BLK is used as a unit of data erasure. The memory cell array 10 is provided with multiple bit lines and multiple word lines. In one example, each memory cell is associated with one bit line and one word line. The configuration of the memory cell array 10 will be described in more detail later.

The command register 11 stores a command CMD received by the memory device 3 from the memory controller 2. Examples of the command CMD include instructions to cause the sequencer 13 to conduct read, write, and erase operations, etc.

The address register 12 stores address information ADD received by the memory device 3 from the memory controller 2. The address information ADD includes, for example, a block address BAd, a page address PAd, and a column address CAd. In an exemplary operation, the block address BAd, the page address PAd, and the column address CAd are used for the selection of a block BLK, a word line, and a bit line, respectively.

The sequencer 13 takes total control over operations of the memory device 3. For example, the sequencer 13 controls the driver module 14, the row decoder module 15, the sense amplifier module 16, etc. to perform read, write, and erase operations, etc., according to the command CMD held at the command register 11.

The driver module 14 generates voltage for use in each of the read, write, and erase operations, etc. In an exemplary operation, the driver module 14, based on the page address PAd stored in the address register 12, applies the generated voltage to a signal line corresponding to the selected word line.

The row decoder module 15, based on the block address BAd stored in the address register 12, selects a single corresponding block BLK in the memory cell array 10. In an exemplary operation, the row decoder module 15 here transfers the voltage applied to the signal line corresponding to the selected word line to the selected word line in the selected block BLK.

The sense amplifier module 16 in a write operation applies a given voltage to each bit line according to write data DAT received from the memory controller 2. Also, the sense amplifier module 16 in a read operation determines data stored in a memory cell based on the voltage of the corresponding bit line and transfers the result of determination to the memory controller 2 as read data DAT.

### 1.1.3 Circuit Configuration of Memory Cell Array

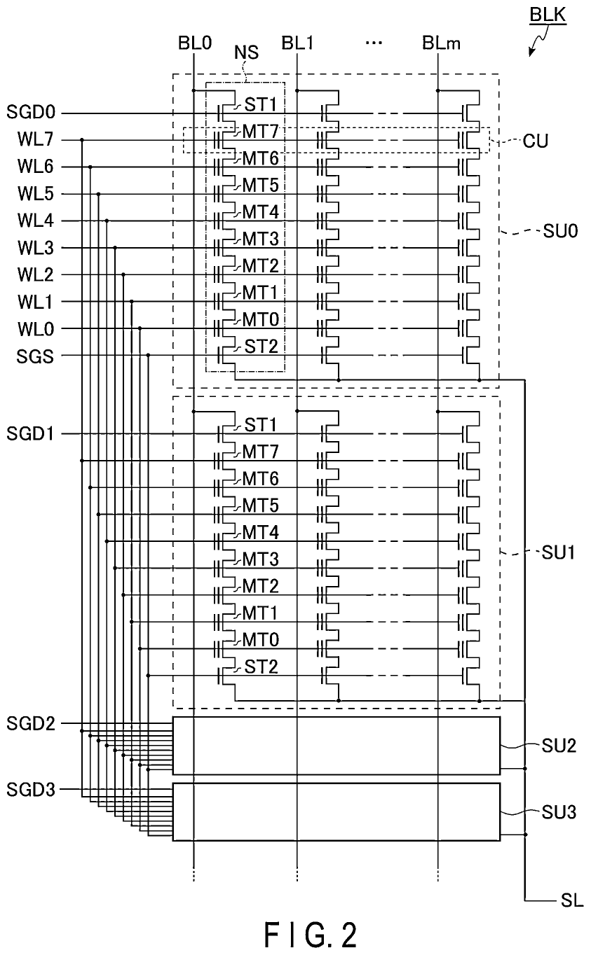

FIG. 2 is a circuit diagram showing an exemplary circuit configuration of a memory cell array fabricated in the memory device according to the first embodiment. FIG. 2 shows one of the multiple blocks BLK included in the memory cell array 10. As shown in FIG. 2, each block BLK includes, for example, four string units SU0 to SU3.

Each string unit SU includes multiple NAND strings NS associated with respective bit lines BL0 to BLm, where m is an integer equal to or greater than 1. The number of bit lines BL may be any number including 1. The NAND strings NS each include, as one example, memory cell transistors MT0 to MT7 and select transistors ST1 and ST2. The memory cell transistors MT each include a control gate and a charge accumulating portion, and each store data in a non-volatile manner. The select transistors ST1 and ST2 are each used for the selection of an applicable string unit SU in various operations.

In each NAND string NS, the memory cell transistors MT0 to MT7 are coupled in series. The select transistor ST1 has its drain coupled to the associated bit line BL. The source of the select transistor ST1 is coupled to one end of the serially coupled memory cell transistors MT0 to MT7. The select transistor ST2 has its drain coupled to the other end of the serially coupled memory cell transistors MT0 to MT7. The source of the select transistor ST2 is coupled to a source line SL.

In one block BLK, the memory cell transistors MT0 to MT7, each provided in multiple numbers, have their control gates coupled to respective word lines WL0 to WL7. The multiple select transistors ST1 in each of the string units SU0 to SU3 have their gates coupled to the respective and corresponding one of select gate lines SGD0 to SGD3. The multiple select transistors ST2 have their gates coupled to a select gate line SGS.

The bit lines BL0 to BLm are assigned respective column addresses differing from one another. Each bit line BL is shared by the NAND strings NS having the same column address, over the multiple blocks BLK. The word lines WL0 to WL7 are provided for each block BLK. In one example, the source line SL is shared by multiple blocks BLK.

A set of multiple memory cell transistors MT coupled to a common word line WL within one string unit SU is called, for example, a “cell unit CU”. For example, the storage capacity of a cell unit CU constituted by the memory cell transistors MT each adapted to store 1-bit data is defined as “1-page data”. Each cell unit CU may have a storage capacity of 2-page data or more according to the number of bit of data to be stored in its memory cell transistors MT.

Note that the memory cell array 10 included in the memory device 3 according to the first embodiment is not limited to the exemplary circuit configuration described above. For example, the number of string units SU in each block BLK may be discretionarily set. The numbers of the memory cell transistors MT and the select transistors ST1 and ST2 in each NAND string NS may also be discretionarily set.

### 1.1.4 Bonded Structure of Memory Device

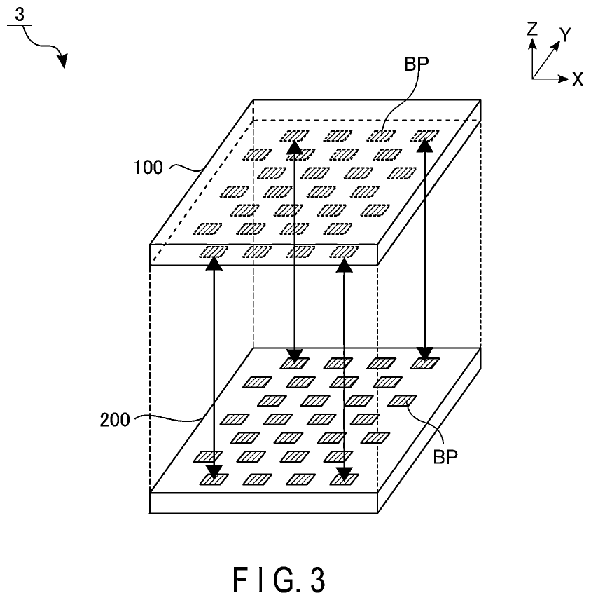

FIG. 3 is a perspective view generally showing a bonded structure of the memory device according to the first embodiment.

As shown in FIG. 3, the memory device 3 includes a memory chip 100 and a circuit chip 200. The memory chip 100 includes a structure or configuration corresponding to the memory cell array 10. The circuit chip 200 includes a structure or configuration corresponding to, for example, the command register 11, the address register 12, the sequencer 13, the driver module 14, the row decoder module 15, and the sense amplifier module 16.

The memory chip 100 and the circuit chip 200 each include multiple bonding pads BP. The memory device 3 is formed by bonding the memory chip 100 and the circuit chip 200 to each other via the multiple bonding pads BP.

In the description below, the interface (bonding interface) through which the memory chip 100 and the circuit chip 200 are bonded together will be called an “XY plane”. Directions orthogonal to each other within the XY plane will be called an “X direction” and a “Y direction”, respectively. A direction substantially perpendicular to the XY plane and extending from the memory chip 100 to the circuit chip 200 will be called a “Z1 direction”. A direction substantially perpendicular to the XY plane and extending from the circuit chip 200 to the memory chip 100 will be called a “22 direction”. The description will use a “Z direction” when a distinction between the Z1 direction and the 22 direction is not intended.

1.1.5 Planar Layout of Memory device

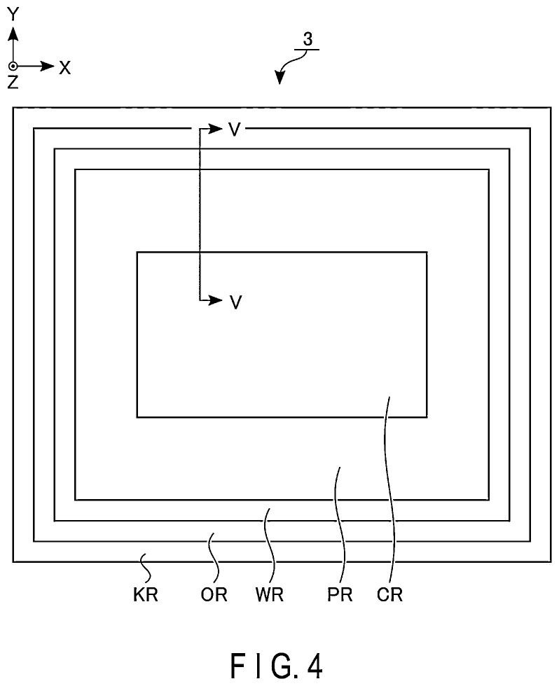

Next, a planar layout of the memory device according to the first embodiment will be described. FIG. 4 is a plan view showing an exemplary planar layout of the memory device according to the first embodiment.

As shown in FIG. 4, the memory device 3 in one example is divided into a core region CR, a peripheral circuit region PR, a wall region WR, an outer peripheral region OR, and a kerf region KR.

The core region CR here is, in the Z direction perspective, a rectangular region located at the center of the memory device 3. In the core region CR of the memory chip 100, the memory cell array 10 is arranged. In the core region CR of the circuit chip 200, members such as the row decoder module 15 and the sense amplifier module 16 may be arranged. Note that the core region CR may be provided in any number and any shape, which can be discretionarily designed.

The peripheral circuit region PR is a rectangular ring region surrounding the outer periphery of the core region CR. In one example, in the peripheral circuit region PR, members such as the command register 11, the address register 12, the sequencer 13, and the driver module 14 may be arranged.

The wall region WR is a rectangular ring region surrounding the outer periphery of the peripheral circuit region PR. In the wall region WR, a member or members for stabilizing the electric potentials of a power supply line, a well, etc., by keeping the outer periphery of the memory device 3 at the same electric potential (ground potential VSS) are provided. For example, such a member or members provided in the wall region WR have a function of releasing static electricity to the substrate. This prevents the static electricity from damaging the circuit components.

The outer peripheral region OR is a rectangular ring region surrounding the outer periphery of the wall region WR. The outer peripheral region OR has a function of preventing a crack or the like, which occurs at the end part of the memory device 3 due to a dicing process, from reaching the inside of the memory device 3. The dicing process refers to a process of cutting a wafer having a plurality of the formed memory devices 3 into chip units.

The kerf region KR is a rectangular ring region surrounding the outer periphery of the outer peripheral region OR. The kerf region KR is a region including the end part of the memory device 3. The kerf region includes a region of the wafer which is between the formed memory devices 3. The dicing process cuts the Kerf region KR so that the memory devices 3 formed on the wafer are separated into chip units. In one example, the kerf region KR is provided with alignment marks, etc., used for the manufacture of the memory devices 3. Structural members in the kerf region KR may be removed by the dicing process.

### 1.1.6 Sectional Structure of Memory Device

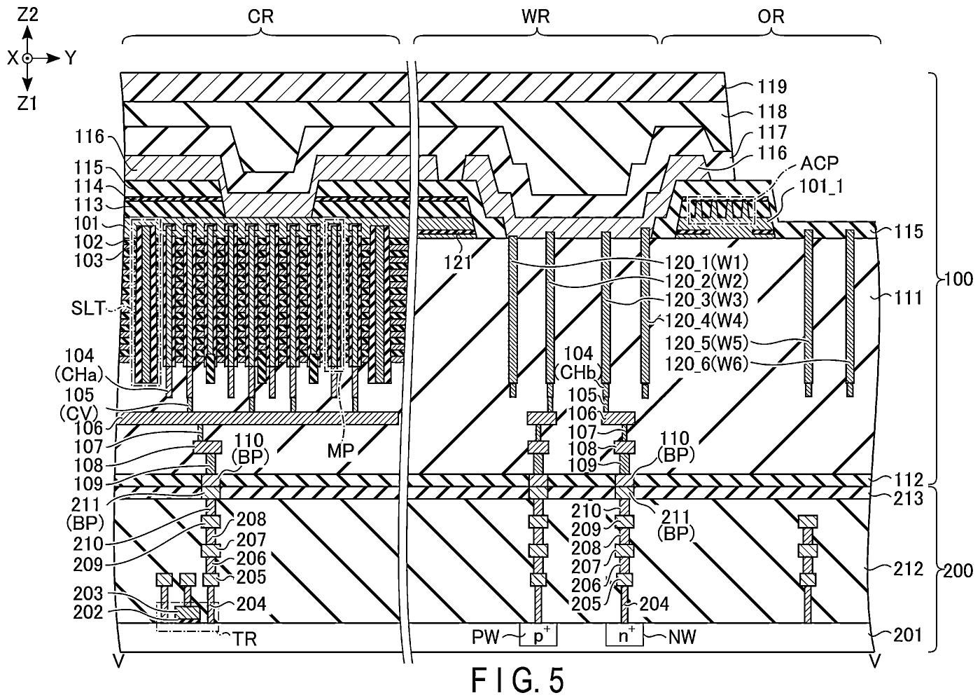

Next, a sectional structure of the memory device according to the first embodiment will be described. FIG. 5 is a sectional view taken along the line V-V in FIG. 4 and shows an exemplary sectional structure of the memory device according to the first embodiment. FIG. 5 sets forth the core region CR, the wall region WR, and the outer peripheral region OR among the regions included in the cross-section along the line V-V in FIG. 4.

As shown in FIG. 5, the memory chip 100 includes a semiconductor layer 101, insulator layers 102, 111, 112, 113, 114, 115, 117, 118, and 121, interconnect layers 103, 106, 108, and 116, conductors 104, 105, 107, and 109, electrodes 110, a surface protective layer 119, a wall structure W, members SLT, and memory pillars MP. The circuit chip 200 includes a semiconductor substrate 201, an N-type impurity diffusion region NW, a P-type impurity diffusion region PW, a transistor TR, a gate insulator 202, a gate electrode 203, conductors 204, 206, 208, and 210, interconnect layers 205, 207, and 209, electrodes 211, and insulator layers 212 and 213.

### 1.1.6.1 Sectional Structure of Memory Chip

The structure of the memory chip 100 will be described first.

### (Core Region)

The core region CR of the memory chip 100 will be described. The core region CR of the memory chip 100 is provided with the memory cell array 10 and a variety of interconnects for the connections between the memory cell array 10 and the circuit chip 200.

The semiconductor layer 101 extends over the XY plane. The semiconductor layer 101 arranged in the core region CR functions as the source line SL. The semiconductor layer 101 contains, for example, silicon. In the core region CR, multiple insulator layers 102 and multiple interconnect layers 103 are stacked alternately and one by one on the Z1 direction top surface of the semiconductor layer 101. In the example shown in FIG. 5, ten insulator layers 102 and ten interconnect layers 103 are stacked alternately and one by one. In other words, multiple interconnect layers 103 stacked at a distance from each other in the Z direction are provided between the circuit chip 200 and the semiconductor layer 101. The multiple interconnect layers 103 each extend in the X direction. The multiple interconnect layers 103 each function as one of the word lines WL, or the select gate line SGD or SGS. The insulator layers 102 contain silicon oxide as an insulating material. The interconnect layers 103 contain, for example, tungsten (W) as a conducting material.

The core region CR includes multiple members SLT. In one example, the members SLT are plate members extending over the XZ plane. The multiple members SLT are arranged in the Y direction. Multiple memory pillars MP are provided between the neighboring members SLT. In one example, each memory pillar MP has a cylindrical shape extending in the Z direction. The structures of the members SLT and the memory pillars MP will be described in more detail later.

The conductor 104 is provided on the Z1 direction top surface of each memory pillar MP. In one example, each conductor 104 provided in the core region CR has a cylindrical shape extending in the Z direction. The conductor 105 is provided on the Z1 direction top surface of the conductor 104. In one example, each conductor 105 provided in the core region CR has a cylindrical shape extending in the Z direction. Further, the interconnect layer 106 is provided on the Z1 direction top surface of the conductor 105. In one example, multiple interconnect layers 106 arranged in the X direction and each extending in the Y direction are provided in the core region CR. Each of the multiple memory pillars MP is electrically coupled to one of the multiple interconnect layers 106 via the associated conductors 104 and 105. The conductors 104 and 105 electrically coupled to the memory pillar MP function as contacts CHa and CV, respectively. The interconnect layer 106 electrically coupled to the memory pillar MP functions as a bit line BL. The conductors 104 contain, for example, tungsten. The conductors 105 and the interconnect layers 106 contain, for example, copper.

The conductor 107 is provided on the Z1 direction top surface of the interconnect layer 106. In one example, each conductor 107 provided in the core region CR has a cylindrical shape extending in the Z direction. The interconnect layer 108 is provided on the Z1 direction top surface of the conductor 107. The conductor 109 is provided on the Z1 direction top surface of the interconnect layer 108. In one example, each conductor 109 provided in the core region CR has a cylindrical shape extending in the z direction. In the core region CR, the electrode 110 is provided on the Z1 direction top surface of the conductor 109. The electrode 110 is electrically coupled to the corresponding electrode 211 of the circuit chip 200. The electrodes 110 and 211 function as bonding pads BP.

The conductors 107 and 109, the interconnect layers 108, and the electrodes 110 contain, for example, copper as a conducting material. Note that the number of layers constituting the multi-layered interconnect structure provided between the interconnect layer 106 and the electrode 110 may be discretionarily determined.

The insulator layer 111 is provided to cover the insulator layers 102, the interconnect layers 103, the memory pillars MP, the members SLT, the conductors 104, the conductors 105, the interconnect layers 106, the conductors 107, the interconnect layers 108, and the conductors 109. The insulator layer 112 is provided on the Z1 direction top surface of the insulator layer 111. A plurality of the electrodes 110 are provided in the same layer as the insulator layer 112. The insulator layer 112 is in contact with the insulator layer 213 of the circuit chip 200.

The insulator layers 113 and 114 are provided on the Z2 direction top surface of the semiconductor layer 101. The insulator layer 115 is provided to cover the semiconductor layer 101 and the insulator layers 113 and 114. The insulator layers 113 and 115 contain, for example, silicon oxide as an insulating material. For the insulator layer 114, an insulating material that has an anti-oxidation function for metal (e.g., copper) is employed. The insulator layer 114 contains, for example, silicon carbonitride (SiCN) or silicon nitride (SiN). The insulator layer 114 may be omitted.

The interconnect layer 116 is provided on the Z2 direction top surface of the insulator layer 115. The interconnect layer 116 in the core region CR contacts the semiconductor layer 101 in a region where the insulator layers 113 to 115 once formed on the semiconductor layer 101 have been removed. As such, the interconnect layer 116 provided in the core region CR functions as a part of the interconnect electrically coupling the semiconductor layer 101 (i.e., the source line SL) to the circuit chip 200. The interconnect layer 116 contains, for example, aluminum (Al) and a barrier metal covering the aluminum (Al).

The insulator layer 117 is provided on the Z2 direction top surface of the interconnect layer 116. The insulator layer 118 is provided on the Z2 direction top surface of the insulator layer 117. Also, the surface protective layer 119 is provided on the Z2 direction top surface of the insulator layer 118. The insulator layer 117 contains, for example, silicon oxide as an insulating material. The insulator layer 118 contains, for example, silicon nitride as an insulating material with low water permeability. The surface protective layer 119 contains, for example, a resin material such as polyimide.

### (Wall Region)

Next, a description will be given of the wall region WR of the memory chip 100.

The wall region WR is provided with one or more wall structures W and a variety of interconnects for the connections between the wall structures W and the circuit chip 200. In one example, the wall structures W include wall structures W1, W2, W3, and W4.

In the wall region WR, portions of the semiconductor layer 101 and the insulator layers 113 to 115 have been removed. The interconnect layer 116 in the wall region WR contacts the wall structures W2 and W3 in a region where the semiconductor layer 101 and the insulator layers 113 to 115 have been removed. The interconnect layer 116 in the wall region WR may be separate from the wall structures W1 and W4 in the region where the semiconductor layer 101 and the insulator layers 113 to 115 have been removed. The interconnect layer 116 provided in the wall region WR is electrically isolated from the interconnect layer 116 provided in the core region CR. The insulator layer 115 is provided between the interconnect layer 116 provided in the wall region WR and the semiconductor layer 101 and the insulator layers 113 and 114 which remain in the wall region WR. The insulator layer 121 is provided within the semiconductor layer 101 remaining in the wall region WR. The insulator layer 121 contains, for example, silicon oxide.

The wall structure W1 has, in the Z direction perspective, a rectangular ring shape surrounding the core region CR. Also, the wall structure W2 in the Z direction perspective has a rectangular ring shape surrounding the wall structure W1. The wall structure W3 in the Z direction perspective has a rectangular ring shape surrounding the wall structure W2. The wall structure W4 in the Z direction perspective has a rectangular ring shape surrounding the wall structure W3. With the wall structures W1 and W4, formation of the wall structures W2 and W3 at a desired Z direction length is guaranteed in the process of forming the wall structures W2 and W3.

The wall structures W1 to W4 each extend in the Z direction. The wall structures W1 to W4 each cross extensions of the respective interconnect layers 103. Each of the wall structures W1 and W4 has a 22 direction end which may differ in position from the 22 direction ends of the wall structures W2 and W3. More specifically, the Z2 direction ends of the wall structures W2 and W3 are positioned at the same or equivalent level within the interconnect layer 116. On the other hand, the Z2 direction end of the wall structure W1 may be positioned on a more Z1 direction side than each of the 22 direction ends of the wall structures W2 and W3. The Z2 direction end of the wall structure W4 may be positioned on a more Z2 direction side than each of the 22 direction ends of the wall structures W2 and W3.

The Z1 direction end of the wall structure W2 and the Z1 direction end of the wall structure W3 are electrically coupled to the respective electrodes 211 of the circuit chip 200 via the corresponding conductor 104, conductor 105, interconnect layer 106, conductor 107, interconnect layer 108, conductor 109, and electrode 110. This endows the wall structures W2 and W3 with a function of preventing a circuit breakage which occurs due to static electricity. Meanwhile, the Z1 direction end of the wall structure W1 and the Z1 direction end of the wall structure W4 are each coupled to the corresponding conductor 104, but not coupled to the conductor 105 or other subsequent conductor members via the conductor 104. As such, the wall structures W1 and W4 may not have a function of preventing a circuit breakage occurring due to static electricity. Note that each of the conductors 104 coupled to the respective Z1 direction ends of the wall structures W1 to W4 does not cross the extensions of the interconnect layers 103.

In one example, the conductor 104, the conductor 105, the interconnect layer 106, the conductor 107, the interconnect layer 108, the conductor 109, and the electrode 110 which are electrically coupled to the wall structure W2 each have, in the Z direction perspective, a rectangular ring shape surrounding the core region CR. Also in one example, the conductor 104, the conductor 105, the interconnect layer 106, the conductor 107, the interconnect layer 108, the conductor 109, and the electrode 110 which are electrically coupled to the wall structure W3 each have, in the Z direction perspective, a rectangular ring shape surrounding the respective one of the conductor 104, the conductor 105, the interconnect layer 106, the conductor 107, the interconnect layer 108, the conductor 109, and the electrode 110 which are electrically coupled to the wall structure W2.

Of the interconnect layer 106 electrically coupled to the wall structure W2, a portion connected to the conductor 107 is located on the core region CR side with respect to a portion connected to the conductor 105. Accordingly, the conductor 105 and the conductor 107, connected to the respective top and bottom surfaces of the interconnect layer 106 electrically coupled to the wall structure W2, do not overlap each other in the Z direction. On the other hand, of the interconnect layer 106 electrically coupled to the wall structure W3, a portion connected to the conductor 107 is located on the outer peripheral region OR side with respect to a portion connected to the conductor 105. Accordingly, the conductor 105 and the conductor 107, connected to the respective top and bottom surfaces of the interconnect layer 106 electrically coupled to the wall structure W3, do not overlap each other in the Z direction.

### (Outer Peripheral Region)

Next, the outer peripheral region OR of the memory chip 100 will be described.

The semiconductor layer 101 provided in the outer peripheral region OR is electrically isolated from the semiconductor layers 101 provided in the core region CR and the wall region WR. In the description below, the semiconductor layer 101 provided in the outer peripheral region OR may also be called a “semiconductor layer 101_1”. The semiconductor layer 101_1 is at least partially out of the coverage (protection) of the surface protective layer 119. In other words, at least a part of the semiconductor layer 101_1 is not present between the circuit chip 200 and the surface protective layer 119 in the Z direction.

The semiconductor layer 101_1 has, on its Z2 direction top surface, multiple protrusions ACP each extending in the Z2 direction. In one example, the protrusions ACP penetrate through the insulator layer 113. The Z2 direction top surfaces of the protrusions ACP are in contact with the insulator layer 114. The insulator layer 121 provided within the semiconductor layer 101_1 is divided by the semiconductor layer 101_1 at the portion overlapping the protrusions ACP in the Z direction. The protrusions ACP, in one example, are utilized in the manufacture of the memory chip 100 to ground the semiconductor layer 101 onto the substrate (not shown in the figure) of the memory chip 100 so that the occurrence of arcing due to the charging-up of the semiconductor layer 101 is prevented during dry etching. The protrusions ACP may be omitted.

The outer peripheral region OR includes one or more wall structures W. In one example, the wall structures W here include wall structures W5 and W6.

In the outer peripheral region OR, portions of the semiconductor layer 101, the interconnect layer 116, and the insulator layers 113, 114, 117, and 118 have been removed. The insulator layer 115 in the outer peripheral region OR contacts the wall structures W5 and W6 in a region where the semiconductor layer 101, the interconnect layer 116, and the insulator layers 113, 114, 117, and 118 have been removed.

The wall structure W5 in the Z direction perspective has a rectangular ring shape surrounding the wall structure W4. The wall structure W6 in the Z direction perspective has a rectangular ring shape surrounding the wall structure W5.

The wall structures W5 and W6 each extend in the Z direction. The wall structures W5 to W6 each cross extensions of the respective interconnect layers 103. The Z1 direction end of the wall structure W5 and the Z1 direction end of the wall structure W6 are each coupled to the corresponding conductor 104, but not coupled to the conductor 105 or other subsequent conductor members via the conductor 104. In one example, the conductor 104 electrically coupled to the wall structure W5 has, in the Z direction perspective, a rectangular ring shape surrounding the conductor 104 electrically coupled to the wall structure W4. Also in one example, the conductor 104 electrically coupled to the wall structure W6 has, in the Z the conductor 104 electrically coupled to the wall structure W5. Note that each of the conductors 104 coupled to the respective Z1 direction ends of the wall structures W5 and W6 does not cross the extensions of the interconnect layers 103.

### 1.1.6.2 Sectional Structure of Circuit Chip

Next, the sectional structure of the circuit chip 200 will be described.

In the core region CR, the semiconductor substrate 201 has, on its 22 direction top surface, the multiple transistors TR. The transistors TR are used as elements in the command register 11, the address register 12, the sequencer 13, the driver module 14, the row decoder module 15, and the sense amplifier module 16. Each transistor TR includes the gate insulator 202, the gate electrode 203, and a source and a drain (not shown in the figure) formed in the semiconductor substrate 201. The gate insulator 202 is provided on the Z2 direction top surface of the semiconductor substrate 201. The gate electrode 203 is provided on the 22 direction top surface of the gate insulator 202.

In the core region CR, the conductors 204 are provided on the respective Z2 direction top surfaces of the gate electrode 203, the source, and the drain. In the wall region WR, the conductors 204 are provided on the respective Z2 direction top surfaces of the N-type impurity diffusion region NW formed in the semiconductor substrate 201 and the P-type impurity diffusion region PW formed in the semiconductor substrate 201. In the outer peripheral region OR, the conductor 204 is provided on the top surface of the semiconductor substrate 201.

The interconnect layers 205 are provided on the respective Z2 direction top surfaces of the conductors 204. The conductors 206 are provided on the respective Z2 direction top surfaces of the interconnect layers 205. The interconnect layers 207 are provided on the respective Z2 direction top surfaces of the conductors 206. The conductors 208 are provided on the respective Z2 direction top surfaces of the interconnect layers 207. The interconnect layers 209 are provided on the respective Z2 direction top surfaces of the conductors 208. The conductors 210 are provided on the respective Z2 direction top surfaces of the interconnect layers 209. The electrodes 211 are provided on the Z2 direction top surfaces of the conductors 210. Note that the conductors 210 and the electrodes 211 may be omitted in the outer peripheral region OR.

In one example, the conductors 204, 206, 208, and 210 provided in the core region CR each have a cylindrical shape extending in the Z direction. In one example, the conductors 204, 206, 208, and 210, the interconnect layers 205, 207, and 209, and the electrodes 211 which are provided in the wall region WR each have, in the Z the core region CR. Similar to these, the N-type impurity diffusion region NW and the P-type impurity diffusion region PW provided in the wall region WR may each have a rectangular ring shape. In one example, the conductors 204, 206, and 208, and the interconnect layers 205, 207, and 209 which are provided in the outer peripheral region OR each have, in the Z direction perspective, a rectangular ring shape surrounding the wall region WR.

The insulator layer 212 is provided on the Z2 direction top surface of the semiconductor substrate 201. The insulator layer 212 is provided to cover the transistor TR, the conductors 204, the interconnect layers 205, the conductors 206, the interconnect layers 207, the conductors 208, the interconnect layers 209, and the conductors 210. The insulator layer 213 is provided on the Z2 direction top surface of the insulator layer 212.

The electrodes 211 are provided on the respective Z2 direction top surfaces of the conductors 210 and in the same layer as the insulator layer 213. The multiple electrodes 211 are coupled to the corresponding electrodes 110 so that they are electrically coupled to various interconnects in the memory chip 100.

The gate electrode 203, the conductors 204, 206, 208, and 210, and the interconnect layers 205, 207, and 209 are made of a conducting material and may contain a metal material, a p-type semiconductor, or an n-type semiconductor. The electrodes 211 contain, for example, copper. The gate insulator 202, the insulator layer 212, and the insulator layer 213 contain, for example, silicon oxide as an insulating material.

### 1.1.7 Members in Core Region, and Wall Structures in Wall Region and Outer Peripheral Region

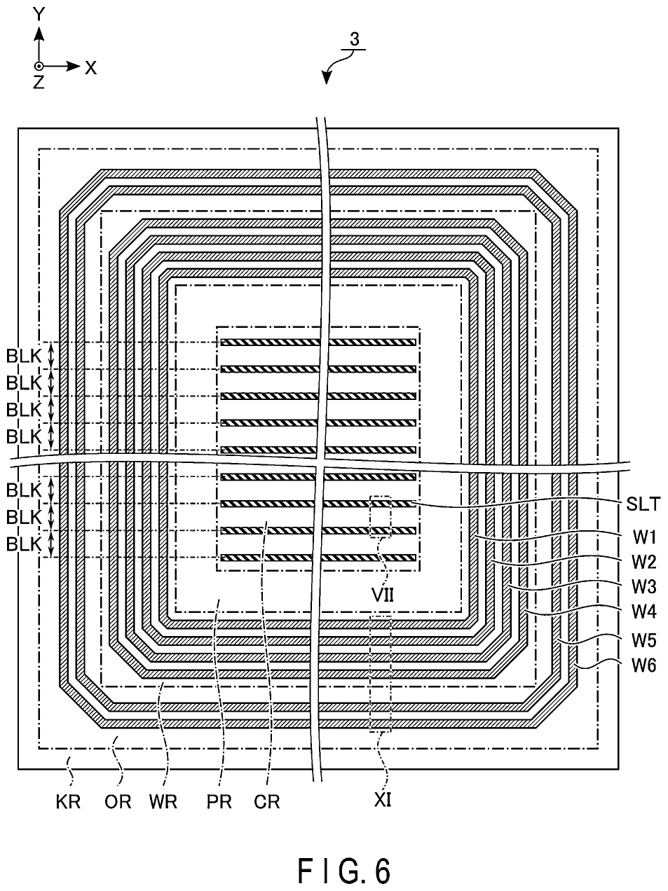

FIG. 6 is a plan view showing an exemplary planar layout of members arranged in the core region, and also wall structures arranged in the wall region and the outer peripheral region, in the memory device according to the first embodiment. FIG. 6 shows the multiple members SLT and the wall structures W1 to W6 by hatching.

The multiple members SLT are arranged in the Y direction in the core region CR. In the core region CR, each region between the neighboring members SLT serves as a block region corresponding to one block BLK.

The wall structures W1 to W6 are provided to surround the core region CR, in which the multiple members SLT are arranged, and also the peripheral circuit region PR surrounding the core region CR. The core region CR and the peripheral circuit region PR are therefore electrically and physically protected from the outside of the wall structures W1 to W6.

### 1.1.7.1 Block Regions

A structure of the block regions will be described.

### (Planar Layout)

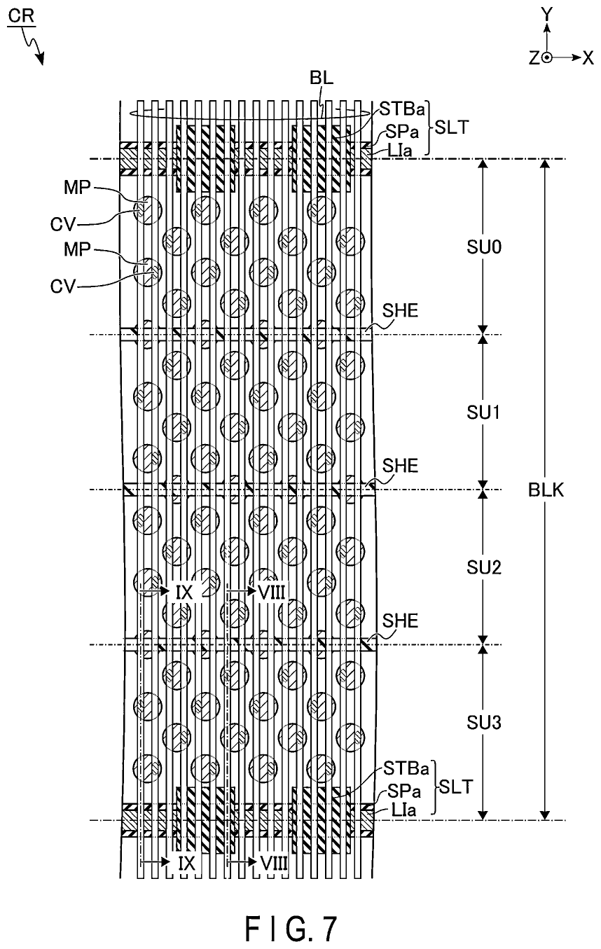

FIG. 7 is a plan view of the area VII in FIG. 6 and shows an exemplary planar layout of the block region in the memory device according to the first embodiment. FIG. 7 sets forth a part of one block region and two members SLT sandwiching the part of the block region. As shown in FIG. 7, the memory cell array 10 in each block region includes three members SHE, multiple memory pillars MP, multiple contacts CV, and multiple bit lines BL. The members SLT each include a contact LIa, spacers SPa, and multiple bridge members STBa.

The contact LIa is a conductor extending over the XZ plane. The spacers SPa are insulators provided on the respective side surfaces of the contact LIa. In other words, the contact LIa is surrounded by the spacers SPa in plan view. The contact LIa and the spacers SPa split, in the Y direction, the stacked interconnect structure constituted by the insulator layers 102 and the interconnect layers 103.

The bridge members STBa are insulators each provided over the contact LIa and the spacers SPa in such a form as to bridge across the contact LIa and spacers SPa in the Y direction. During the process of forming the stacked interconnect structure, the bridge members STBa bridge across a groove where the contact LIa and the spacers SPa are to be formed, so as to serve a function of increasing the strength of the structure split by the groove.

The multiple memory pillars MP each function as, for example, an individual NAND string NS. These multiple memory pillars MP are arranged in, for example, nineteen staggered rows in a region between two neighboring members SLT. Here, in one example, the memory pillars MP in the fifth row, the tenth row, and the fifteenth row from the top (with reference to the figure) each overlap one respective member SHE.

The members SHE are, in one example, insulating plate members extending over the XZ plane. Three members SHE are arranged in the Y direction between the neighboring members SLT. The members SHE each split, in the Y direction, the interconnect layer 103 that corresponds to the select gate lines SGD. The portion between the neighboring members SHE, or the portion between the neighboring members SLT and SHE corresponds to one string unit SU.

The multiple bit lines BL each extend in the Y direction, and are arranged in the X direction. Each bit line BL is arranged to overlap at least one memory pillar MP for each string unit SU. In the example shown in FIG. 7, two bit lines BL together overlap one memory pillar MP. In the structure where multiple bit lines BL together overlap one memory pillar MP, one of such bit lines BL and the corresponding memory pillar MP are electrically coupled to each other via the respective contact CV.

In one example, there is no contact CV between each memory pillar MP that contacts the member SHE, and the bit lines BL. In other words, a contact CV between the memory pillar MP that abuts two different select gate lines SGD and each bit line BL is omitted. The numbers or the layout of the memory pillars MP and the members SHE, arranged between the neighboring members SLT, or other components are not limited to the exemplary structure described with reference to FIG. 7, and may be discretionarily altered. The number of bit lines BL overlapping each memory pillar MP may be discretionarily set.

### (Sectional Structure)

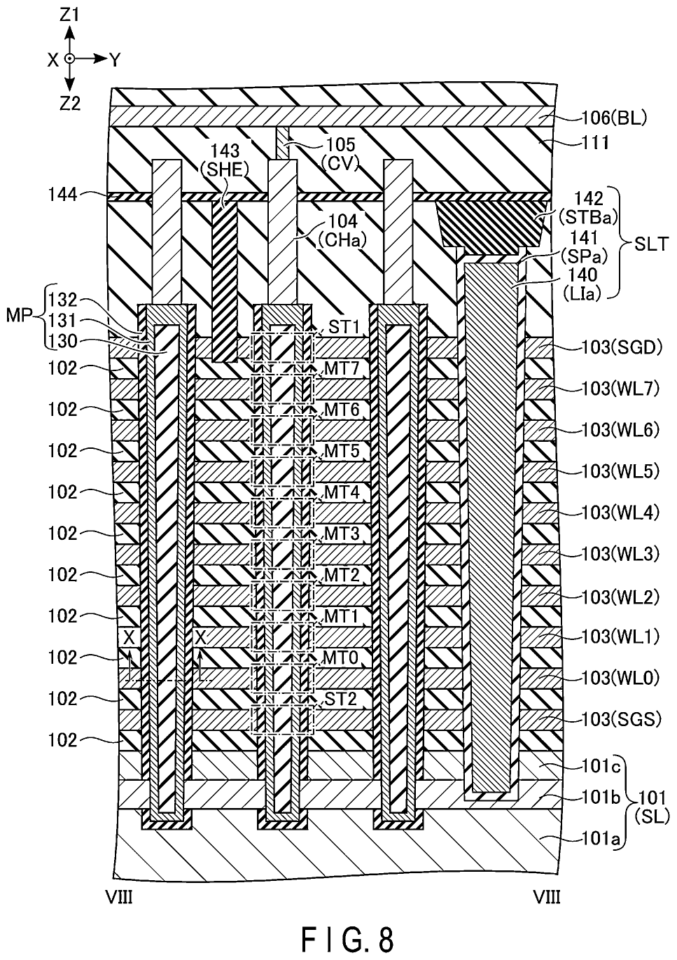

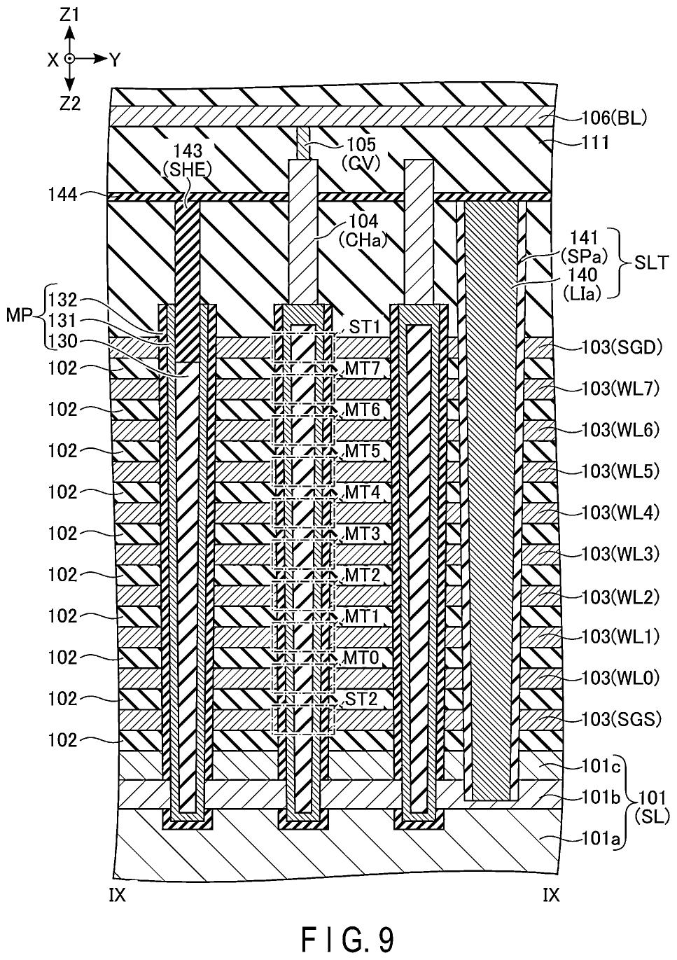

FIG. 8 is a sectional view taken along the line VIII-VIII in FIG. 7 and shows an exemplary sectional structure of the block region in the memory device according to the first embodiment. FIG. 9 is a sectional view taken along the line IX-IX in FIG. 7 and shows an exemplary sectional structure of the block region in the memory device according to the first embodiment.

As shown in FIGS. 8 and 9, the semiconductor layer 101 in one example includes three semiconductor layers 101a, 101b, and 101c. On the Z1 direction top surface of the semiconductor layer 101a, the semiconductor layer 101b is provided. On the Z1 direction top surface of the semiconductor layer 101b, the semiconductor layer 101c is provided. In one example, the semiconductor layer 101b is formed by replacing the insulator layer 121 provided between the semiconductor layer 101a and the semiconductor layer 101c. The semiconductor layers 101a to 101c contain, for example, polysilicon. The semiconductor layers 101a to 101c also contain, for example, phosphorus (P) as a semiconductor impurity.

On the Z1 direction top surface of the semiconductor layer 101, ten insulator layers 102 and ten interconnect layers 103 are stacked alternately and one by one. In the example shown in FIGS. 8 and 9, the ten interconnect layers 103 function as the select gate line SGS, the word lines WL0 to WL7, and the select gate line

SGD in order from the side closer to the semiconductor layer 101. Note that multiple interconnect layers 103 that function as the select gate lines SGS and SGD may be provided. Examples of conductive materials of the interconnect layers 103 include titanium nitride and tungsten which constitute a stacked structure. Here, titanium nitride is provided to cover tungsten. Titanium nitride has a function of serving as a barrier layer for suppressing the oxidation of tungsten, or as an adhesion layer for enhancing the adhesion of tungsten, in the formation of a tungsten film through, for example, chemical vapor deposition (CVD). Also, the interconnect layers 103 may contain a high dielectric constant material such as aluminum oxide. The high dielectric constant material here is provided to cover the conductive materials. In one example, each interconnect layer 103 is provided with the high dielectric constant material such that the high dielectric constant material is in contact with the respective insulator layers 102 located above and below this interconnect layer 103 and also with the side surface of the memory pillar MP. Here, said titanium nitride is provided to be in contact with the high dielectric constant material. The tungsten is provided to be in contact with the titanium nitride and to fill the inside of the interconnect layer 103. The insulator layer 111 is provided on the Z1 direction top surface of the interconnect layer 103 that serves as the select gate line SGD.

The members SLT each include a conductor 140 and insulators 141 and 142. The conductor 140 contains, for example, tungsten and functions as the contact LIa. The conductor 140 has its Z2 direction end (bottom surface) located in the semiconductor layer 101b. The Z1 direction end (top surface) of the conductor 140 is located on a more Z1 direction side than the interconnect layer 103 that functions as the select gate line SGD.

The insulator 141 contains, for example, silicon oxide and functions as the spacers SPa. The insulator 141 covers the side surfaces of the conductor 140, and also the bottom and top surfaces of the conductor 140 in regions which, in the Z direction perspective, overlap the insulator 142. The insulator 141 electrically isolates the multiple interconnect layers 103 from the conductor 140.

The insulator 142 contains, for example, silicon oxide and functions as the bridge member STBa. The insulator 142 is provided on the top surface of the portion of the insulator 141 that is located on the top surface of the conductor 140. The side surfaces of the insulator 142 are in contact with the insulator layer 111.

The bottom and top surfaces of the conductor 140 in regions which do not overlap the insulator 142 in the Z direction perspective are not covered by the insulator 141 but instead contact the semiconductor layer 101b and an insulator layer 144, respectively. The top surface of the conductor 140 in the region not overlapping the insulator 142 in the Z direction perspective is positioned at the same level as the top surface of the insulator 142. That is, the Z1 direction end of the conductor 140 has a dent and rise profile in the X direction.

The members SHE each include an insulator 143. The insulator 143 splits the interconnect layer 103 for functioning as the select gate lines SGD, in the Y direction. The Z2 direction end (bottom surface) of the insulator 143 reaches the insulator layer 102 located between the interconnect layer 103 functioning as the select gate lines SGD and the interconnect layer 103 functioning as the word line WL7.

The insulator layer 144 has a plate shape extending over the XY plane so as to cover the top surface of the member SLT. For the insulator layer 144, an insulating material that has an anti-oxidation function for metal (e.g., copper) is employed.

The memory pillars MP each have a substantially cylindrical shape extending in the Z direction. The memory pillar MP penetrates through the ten interconnect layers 103. The bottom surface of the memory pillar MP reaches the semiconductor layer 101a. The memory pillar MP may have a structure in which multiple pillars are connected in the Z direction.

Next, an internal configuration of the memory pillar MP will be described. Each memory pillar MP includes a core film 130, a semiconductor film 131, and a laminate film 132. The core film 130 extends in the Z direction. In one example, the Z1 direction end of the core film 130 reaches the insulator layer 111, and the 22 direction end of the core film 130 reaches the semiconductor layer 101a. The semiconductor film 131 surrounds and covers the core film 130. In the Z2 direction end of the memory pillar MP, a part of the semiconductor film 131 contacts the semiconductor layer 101b. In the DI direction end of the memory pillar MP, a part of the semiconductor film 131 contacts the conductor 104. The laminate film covers the side surface and the Z2 direction end of the semiconductor film 131, except a portion where the semiconductor film 131 and the semiconductor layer 101b are in contact with each other. The core film 130 contains, for example, an insulator such as silicon oxide. The semiconductor film 131 contains, for example, silicon.

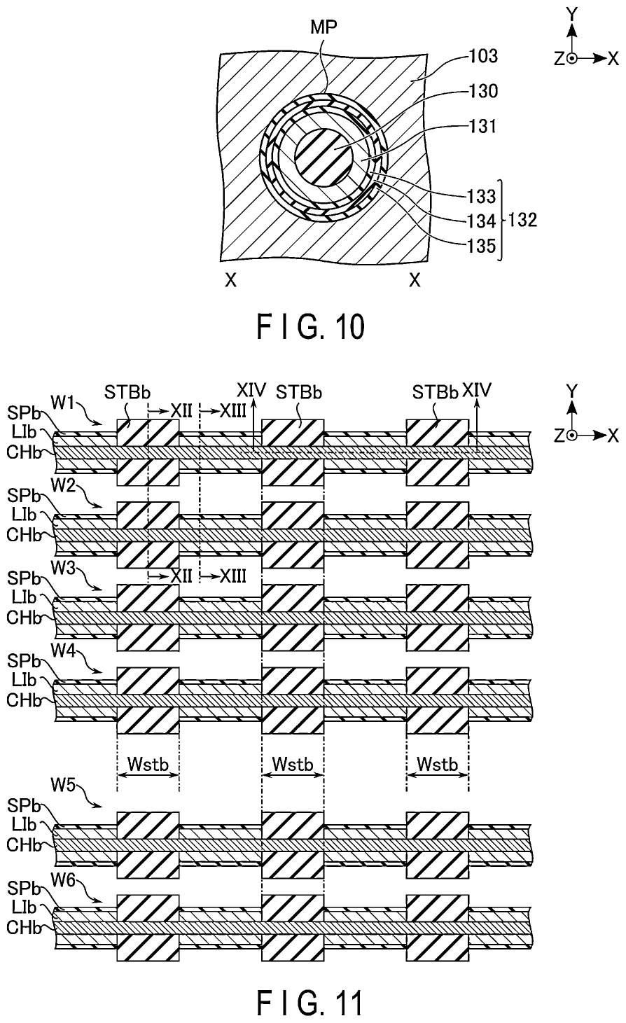

FIG. 10 is a sectional view taken along the line X-X in FIG. 8 and shows an exemplary sectional structure of the memory pillar in the memory device according to the first embodiment. More specifically, what is shown in FIG. 10 is a sectional structure of the memory pillar MP along a layer that is parallel to the XY plane and includes the interconnect layer 103. As shown in FIG. 10, the laminate film 132 in one example includes a tunnel insulator 133, a charge accumulation film 134, and a block insulator 135.

In the cross-section including the interconnect layer 103, the core film 130 is provided at, for example, the central part of the memory pillar MP. The semiconductor film 131 surrounds the side surface of the core film 130. The tunnel insulator 133 surrounds the side surface of the semiconductor film 131. The charge accumulation film 134 surrounds the side surface of the tunnel insulator 133. The block insulator 135 surrounds the side surface of the charge accumulation film 134. The interconnect layer 103 surrounds the side surface of the block insulator 135. The tunnel insulator 133 and the block insulator 135 each contain, for example, silicon oxide. The charge accumulation film 134 has a function of accumulating electric charges and contains, for example, silicon nitride.

The memory pillar MP and the interconnect layers 103 functioning as the respective word lines WL0 to WL7 together form the memory cell transistors MT0 to MT7. Similarly, the combination of the memory pillar MP and the interconnect layer 103 functioning as the select gate line SGD forms the select transistor ST1. The combination of the memory pillar MP and the interconnect layer 103 functioning as the select gate line SGS forms the select transistor ST2. With these components, the memory pillars MP are each capable of functioning as one NAND string NS. 1.1.7.2 Wall Region and Outer Peripheral Region

Next, structures of the wall region WR and the outer peripheral region OR will be described.

### (Planar Layout)

FIG. 11 is a plan view of the area XI in FIG. 6 and shows an exemplary planar layout of the wall region and the outer peripheral region in the memory device according to the first embodiment. In FIG. 11, portions of the wall structures W1 to W6, and portions of contacts CHb coupled to the respective wall structures W1 to W6 are shown. As shown in FIG. 11, each of the wall structures W1 to W6 in the wall region WR and the outer peripheral region OR includes a contact LIb, spacers SPb, and multiple bridge members STBb.

The contact LIb is a rectangular ring conductor extending in the Z direction. The spacers SPb are insulators provided on the respective side surfaces of the contact LIb. In other words, the contact LIb is surrounded by the spacers SPb in plan view.

The bridge members STBb are insulators each provided over the contact LIb and the spacers SPb in such a form as to bridge across the contact LIb and spacers SPb in the width direction crossing the longitudinal direction (i.e., in the Y direction assumed in FIG. 11). In one example, each bridge member STBb has a length Wstb in the longitudinal direction of the contact LIb and the spacers SPb. During the process of forming the associated wall structure W, the bridge members STBb bridge across a groove where the contact LIb and the spacers SPb are to be formed, so as to serve a function of increasing the strength of the structure split by the groove.

The contact CHb is provided to be in contact with the top of the contact LIb. The contact CHb splits the bridge members STBb. The contact CHb has a smaller length in the width direction than the contact LIb.

### (Sectional Structure)

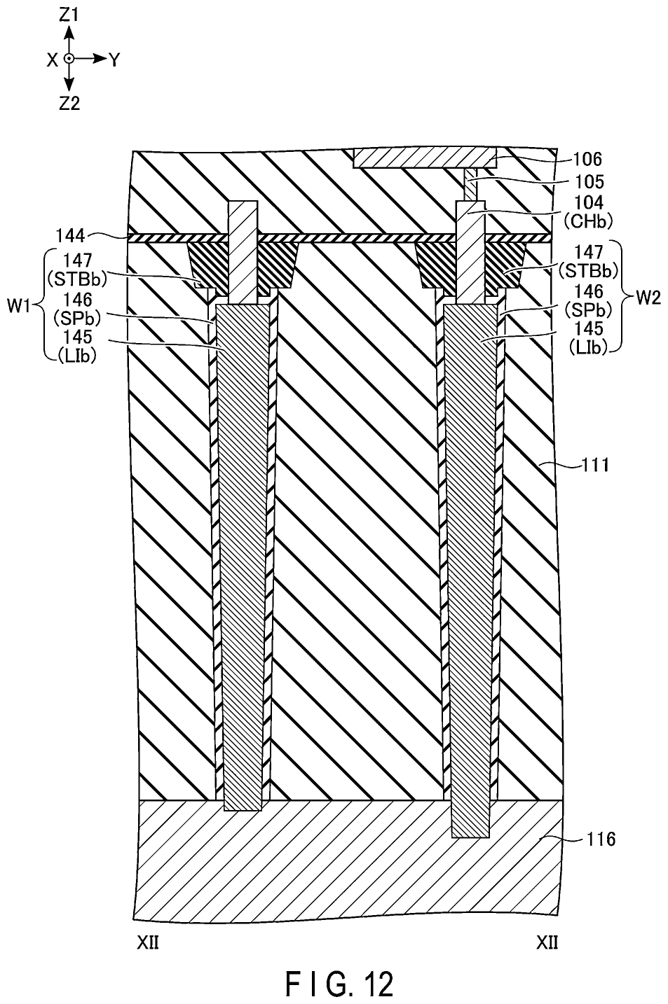

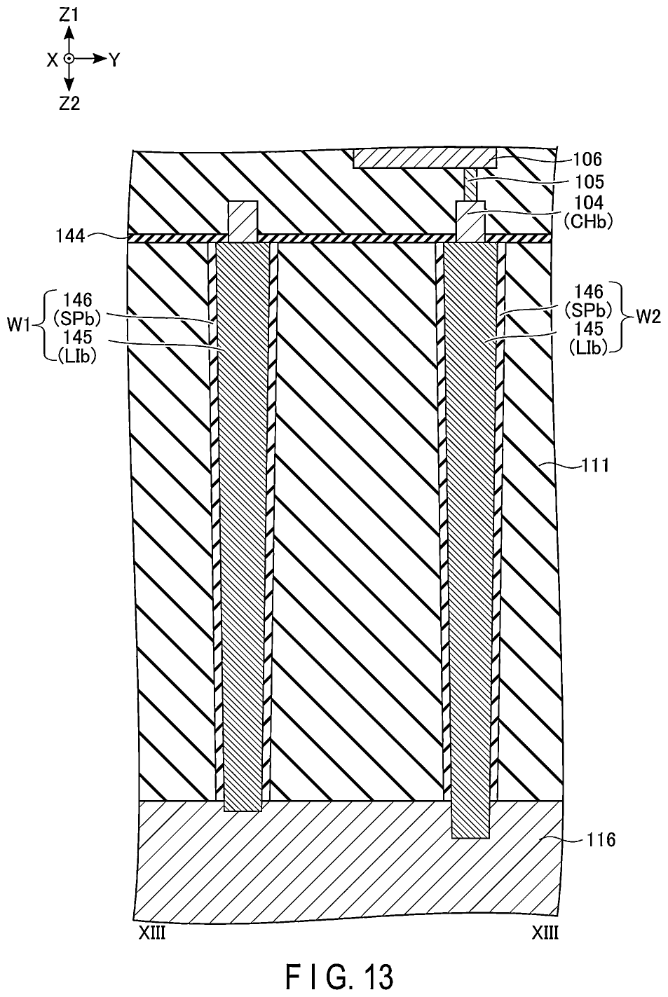

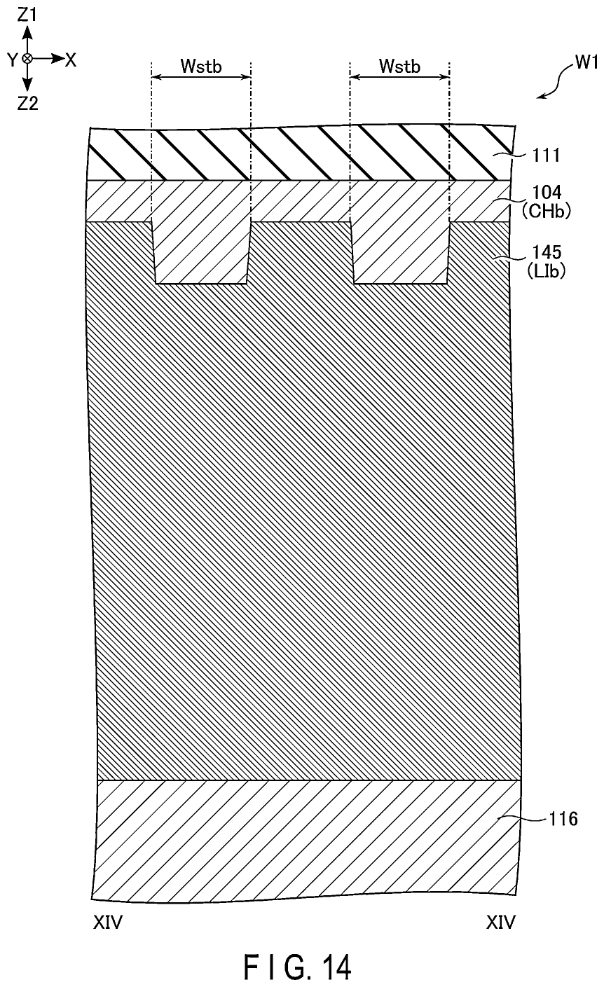

FIG. 12 is a sectional view taken along the line XII-XII in FIG. 11 and shows an exemplary sectional structure of the wall region in the memory device according to the first embodiment. FIG. 13 is a sectional view taken along the line XIII-XIII in FIG. 11 and shows an exemplary sectional structure of the wall region in the memory device according to the first embodiment. FIG. 14 is a sectional view taken along the line XIV-XIV in FIG. 11 and shows an exemplary sectional structure of the wall region in the memory device according to the first embodiment. In FIGS. 12 and 13, width direction sectional structures of the wall structures W1 and W2 are shown. In FIG. 14, a longitudinal direction sectional structure of the wall structure W1 is shown.

As shown in FIGS. 12, 13, and 14, the wall structures W1 and W2 each include a conductor 145 and insulators 146 and 147.

The insulator 146 contains, for example, silicon oxide and functions as the spacers SPb. The insulator 146 covers the side surfaces of the conductor 145, except portions located inside the interconnect layer 116, and also covers the top surface of the conductor 145 in a region which, in the Z direction perspective, overlaps the insulator 147.

The insulator 147 contains, for example, silicon oxide and functions as the bridge member STBb. The insulator 147 is provided on the top surface of the portion of the insulator 146 that is located on the top surface of the conductor 145. The side surfaces of the insulator 147 are in contact with the insulator layer 111.

The top surface of the conductor 145 in the region not overlapping the insulator 147 in the Z direction perspective is not covered by the insulator 146 but instead contacts the insulator layer 144. Also, the top surface of the conductor 145 in the region not overlapping the insulator 147 in the Z direction perspective is positioned at the same level as the top surface of the insulator 147.

The conductor 104, which functions as the contact CHb, penetrates through the insulator layer 144, the insulator 146, and the insulator 147 and contacts the conductor 145.

The conductors 145 and 104 therefore have shapes that form, in their mutually contacting portions, a repeated dent and rise pattern (a dent and rise profile) along the longitudinal direction as if gears mesh together. More specifically, among the portions of the conductor 145 that are in contact with the conductor 104, the portion overlapping the insulator 147 in the width direction perspective (i.e., the dent portion) is located on a more Z2 direction side than the portion not overlapping the insulator 147 in the width direction perspective (i.e., the rise portion). As such, in the Z direction perspective, the conductors 145 and 104 are in contact with each other in the Z direction at two different Z direction positions or levels alternately along the longitudinal direction of the conductors 145 and 104. Note that, in the Z direction perspective, the conductors 145 and 104 are also in contact with each other in their longitudinal direction via the portions connecting these two different Z direction positions (i.e., via the lateral faces in the dent and rise profile). Accordingly, the longitudinal direction length of each dent portion of the conductor 145 substantially equals the length Wstb.

While FIG. 14 assumes the longitudinal direction joining part between the conductors 145 and 104 in the wall structure W1, the wall structures W2 to W6 each include a joining part between the conductors 145 and 104 that is of an equivalent profile to the joining part in the wall structure W1.

### 1.1.8 Sectional Structure of Bonding Pads

Next, a sectional structure of the bonding pads BP will be described.

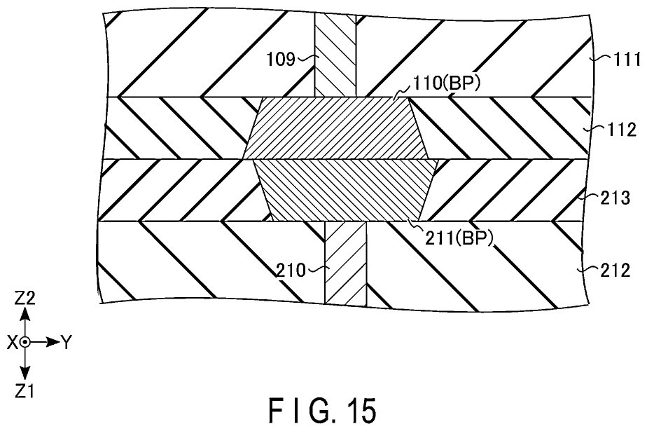

FIG. 15 is a sectional view showing an exemplary sectional structure of the bonding pads in the memory device according to the first embodiment. FIG. 15 shows an example with the electrodes 110 and 211.

As shown in FIG. 15, the electrode 110 is coupled to the electrode 211 in a process for bonding the memory chip 100 and the circuit chip 200. In the example shown in FIG. 15, areas of the respective electrodes 110 and 211 in the bonding interface are substantially equal to each other. Here, use of copper in the electrodes 110 and 211 might cause copper in the electrode 110 and copper in the electrode 211 to merge together, and recognizing the boundary between the copper elements might become difficult. Nevertheless, bonding is recognizable from deformed shapes of the electrodes 110 and 211 bonded with a positional displacement, or from displaced barrier metals for copper (occurrence of discontinuity in the side surfaces).

Also, the electrodes 110 and 211, if formed through a damascene method, each have tapered side surfaces. Accordingly, the Z direction cross-section of a portion where the electrodes 110 and 211 are bonded together shows a non-rectangular profile with non-linear side walls.

In addition to the above, bonding of the electrodes 110 and 211 produces a structure in which a barrier metal covers the bottom, side, and top surfaces of the copper elements forming the electrodes 110 and 211. In contrast, general interconnect layers which employ copper are provided with an insulator layer (silicon nitride, silicon carbonitride, or the like) over the top surface of the copper so as to give an anti-copper-oxidation function, and no barrier metal is provided. Thus, it is possible to distinguish from general interconnect layers even if displacement is not involved in bonding.

### 1.2 Manufacturing Method

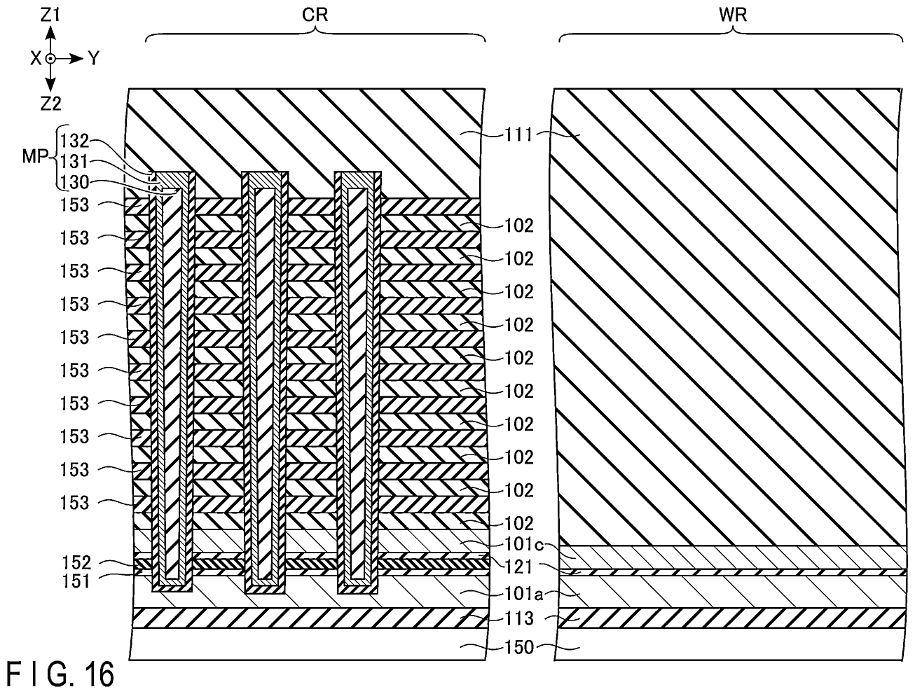

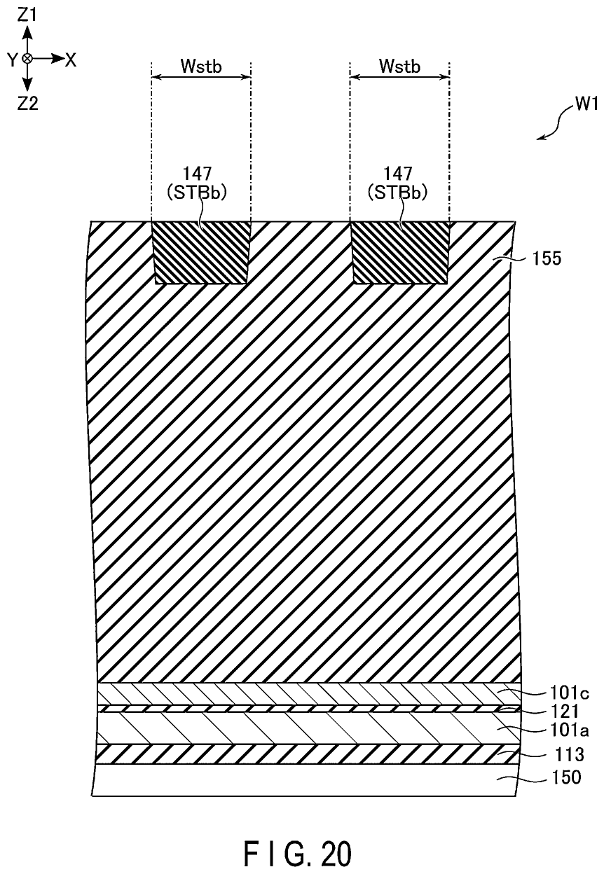

FIGS. 16 to 26 are sectional views each showing an exemplary sectional structure of the memory device according to the first embodiment in a state during the manufacture. Note that FIGS. 16 to 19, 21 to 23, and 25 correspond to the cross-sections shown in FIGS. 8 and 12. FIGS. 20, 24, and 26 correspond to the cross-section shown in FIG. 14.

First, as shown in FIG. 16, a stacked structure and multiple memory pillars MP are formed in the core region CR. More specifically, an insulator layer 113 and a semiconductor layer 101a are provided in this order on the Z1 direction top surface of a semiconductor substrate 150. Subsequently, an insulator layer 151 and a sacrificial member 152 are provided in this order on the Z1 direction top surface of a portion of the semiconductor layer 101a that is located in the core region CR. The insulator layer 151 contains, for example, silicon oxide. The sacrificial members 152 contain, for example, amorphous silicon. An insulator layer 121 and a semiconductor layer 101c are then provided in this order on each of the Z1 direction top surfaces of the sacrificial member 152 and the semiconductor layer 101a.

Subsequently, the stacked structure is formed by repeatedly stacking an insulator layer 102 and a sacrificial member 153 in this order on the Z1 direction top surface of the semiconductor layer 101c in the core region CR. In the stacked structure, multiple holes (not shown in the figure) corresponding to the respective memory pillars MP are formed. The multiple holes are then each filled with a laminate film 132, a semiconductor film 131, and a core film 130 so as to form the memory pillars MP. The stacked structure and other structural elements after formation of the memory pillars MP are covered by an insulator layer 111.

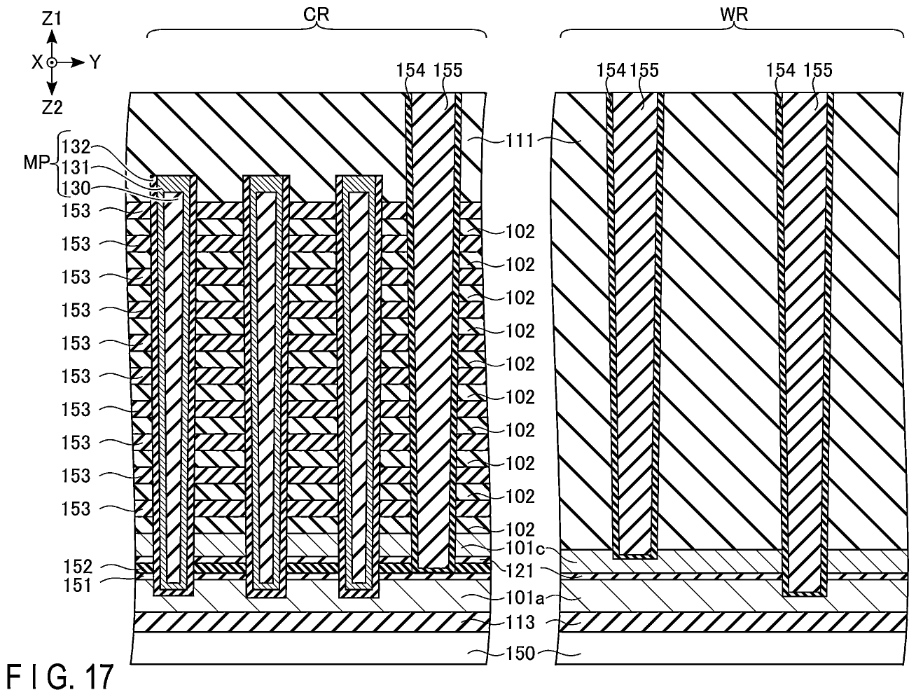

Next, as can be seen from FIG. 17, grooves (not shown in the figure) are formed concurrently in respective regions corresponding to the members SLT and the wall structures W. Each groove corresponding to the member SLT reaches, at its bottom surface, the sacrificial member 152. The bottom surface of each groove corresponding to the wall structure W reaches a more semiconductor substrate 150 side than the semiconductor layer 101c. Note, however, that the bottom surfaces of the grooves corresponding to the wall structures W1 and W4 to W6 may not reach a position on a more semiconductor substrate 150 side than the semiconductor layer 101c. FIG. 17 shows an example where the bottom surface of the groove corresponding to the wall structure W1 and the bottom surface of the groove corresponding to the wall structure W2 are located within the semiconductor layer 101c and the semiconductor layer 101a, respectively. Subsequently, the formed grooves corresponding to the respective members SLT and the wall structures W are each filled with an insulator 154 and a sacrificial member 155. The insulator 154 contains, for example, silicon oxide. The sacrificial member 155 contains, for example, amorphous silicon.

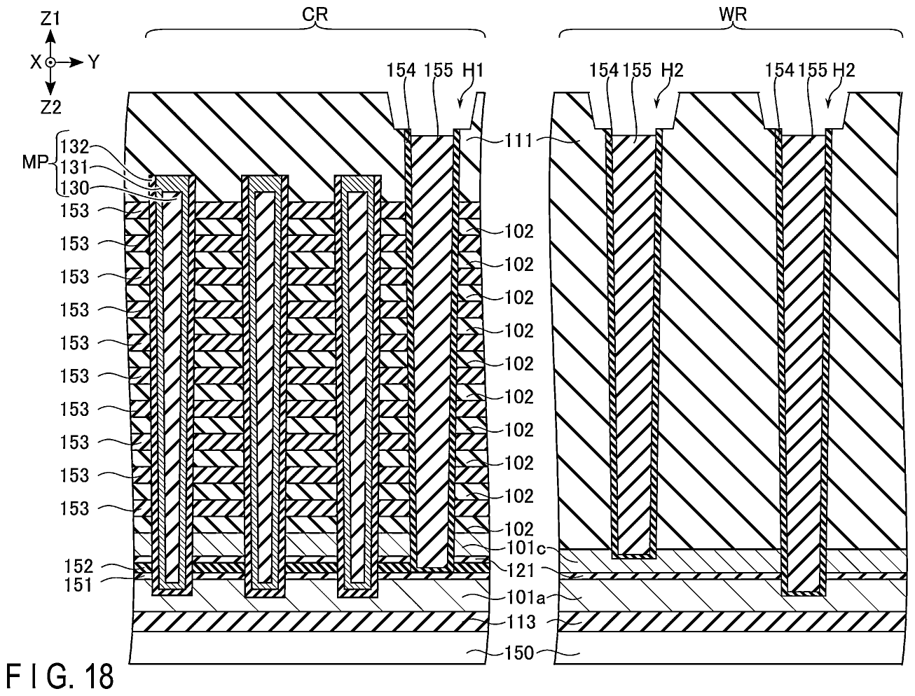

Next, as shown in FIG. 18, holes H1 and H2 are formed in respective regions corresponding to the bridge members STBa and STBb. The holes H1 and H2 each have an opening diameter larger than the width of the groove filled with the insulator 154 and the sacrificial member 155. Also, the width of the opening of the hole H2 along the longitudinal direction of the wall structure W has the length Wstb. With the processing of the holes H2, the Z1 direction top of the sacrificial member 155 in each groove corresponding to the wall structure W is formed in such a shape that a dent portion having the length Wstb is repeated at intervals along the longitudinal direction.

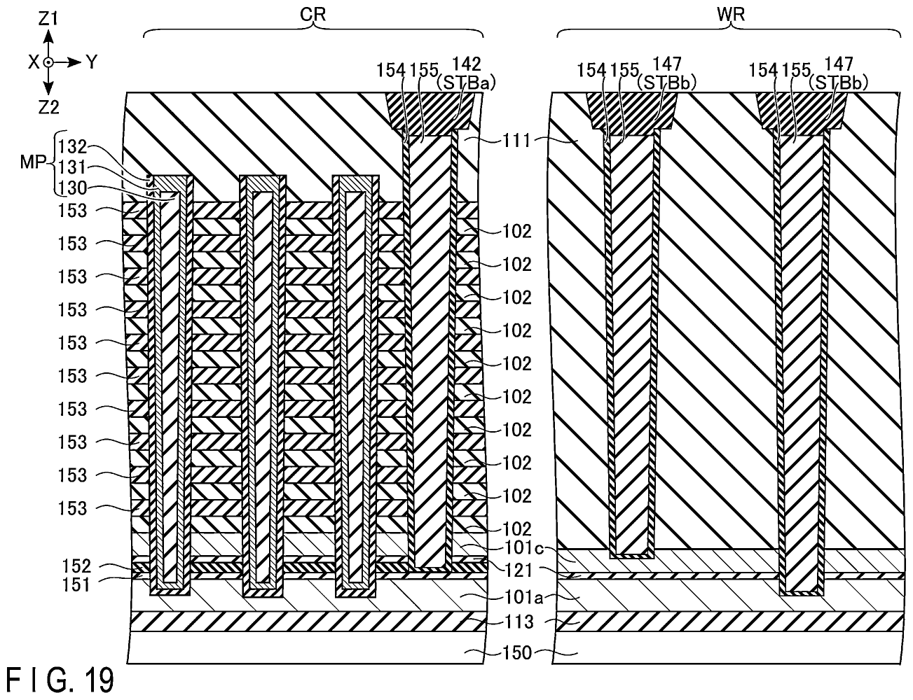

Subsequently, as shown in FIGS. 19 and 20, the holes H1 and H2 are each filled with insulators 142 and 147, respectively. The bridge members STBa and STBb are thus formed. The bridge members STBb are provided to fill the respective dent portions in the Z1 direction top of the sacrificial member 155.

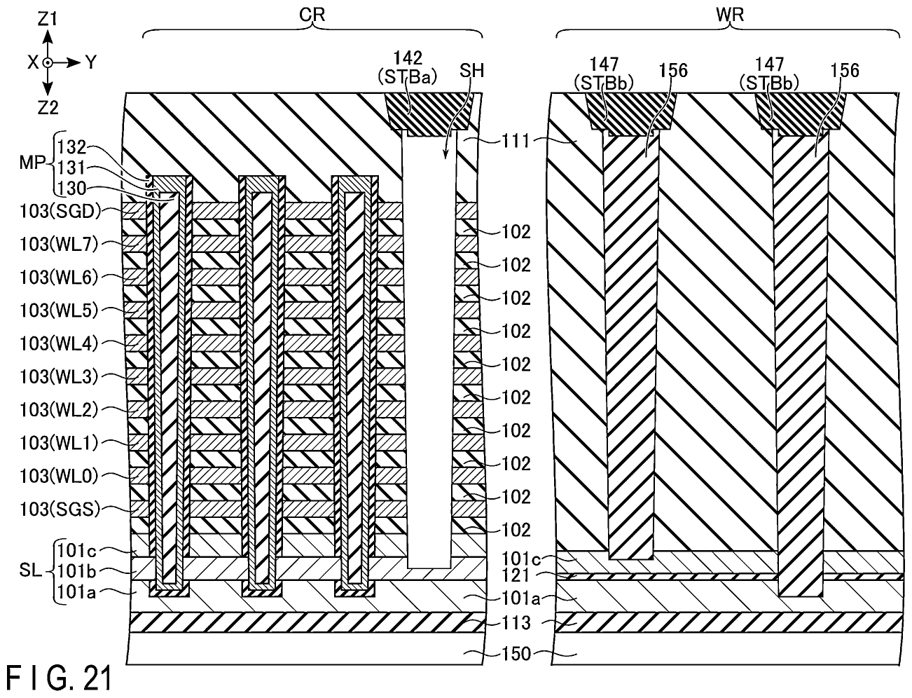

Next, as shown in FIG. 21, the insulators 154 and the sacrificial members 155 that fill the grooves corresponding to the respective members SLT and wall structures W are removed. Subsequently, the grooves corresponding to the wall structures W are again each filled with a sacrificial member 156. The sacrificial member 156 contains, for example, amorphous silicon. The grooves corresponding to the members SLT are thus present as opened grooves SH. Through these grooves SH, replacing processes will be conducted. As the replacing processes, a process for replacing the insulator layers 151 and 121 and the sacrificial member 152 in the core region CR, and a process for replacing the members in the stacked structure are sequentially conducted.

In one example, the process for replacing the insulator layers 151 and 121 and the sacrificial member 152 in the core region CR includes performing wet etching to selectively remove the sacrificial member 152 through the groove SH. Then, the insulator layers 151 and 121, and also a part of the laminate film 132 located on the side surface of each memory pillar MP in the core region CR, are selectively removed by, for example, wet etching through the groove SH. A semiconductor layer 101b is then provided to fill the space left after the removal of the insulator layers 151 and 121 and the sacrificial member 152. This semiconductor layer 101b, and also the semiconductor layers 101a and 101c, together constitute the semiconductor layer 101 functioning as the source line SL. The semiconductor layer 101 is electrically connected to the semiconductor film 131 in each memory pillar MP through contact with the side surface of the semiconductor film 131.

The process for replacing the members in the stacked structure includes selectively removing the sacrificial members 153 by wet etching with a thermal phosphoric acid, etc., through the groove SH. A conductor is then provided through the groove SH to fill each of the spaces left after the removal of the respective sacrificial members 153. Subsequently, the conductor formed inside the groove SH is removed by etch-back processing. This divides the embedded conductor into multiple separate conductor layers. Accordingly, an interconnect layer 103 functioning as the select gate line SGS, interconnect layers 103 functioning as the respective word lines WL, and an interconnect layer 103 functioning as the select gate line SGD are formed. Note that the interconnect layers 103 formed in this process may include a barrier metal. For this form, the formation of the conductors after the removal of the sacrificial members 153 may involve film formation using, for example, titanium nitride as the barrier metal, followed by the tungsten formation.

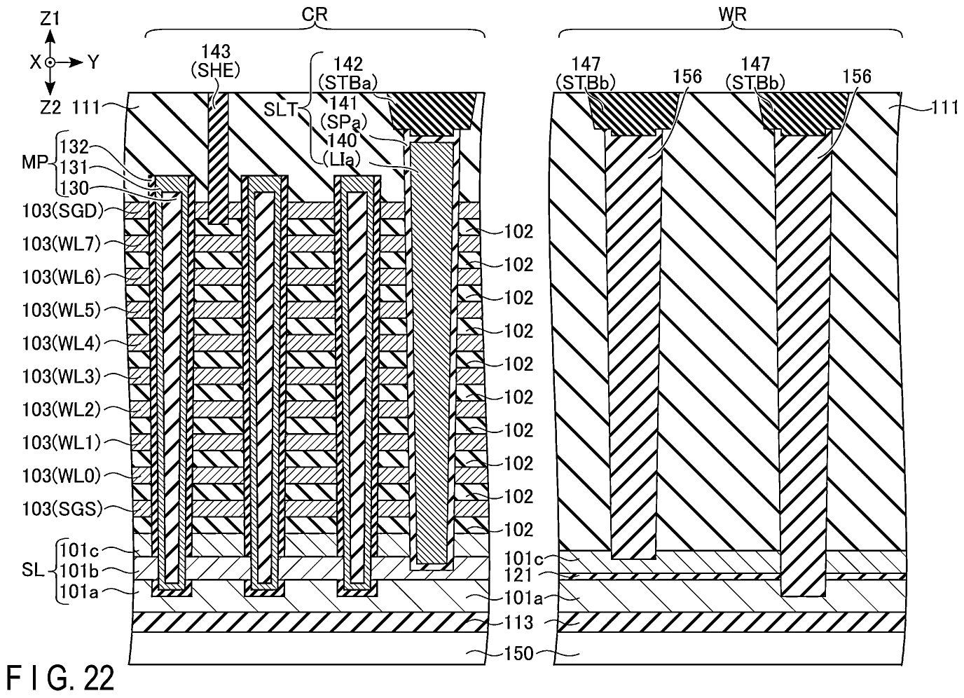

Subsequently, as shown in FIG. 22, spacers SPa and a contact LIa are formed in each groove SH. More specifically, an insulator 141 is formed in the groove SH, and then a part of the insulator 141 formed at the bottom of the groove SH is removed. This exposes a part of the semiconductor layer 101 at the bottom of the groove SH. A conductor 140 is then provided to fill the groove SH. The member SLT is thus formed. The conductor 140 is electrically coupled to the semiconductor layer 101. Meanwhile, the conductor 140 is isolated and insulated from the interconnect layers 103 by the presence of the insulator 141.

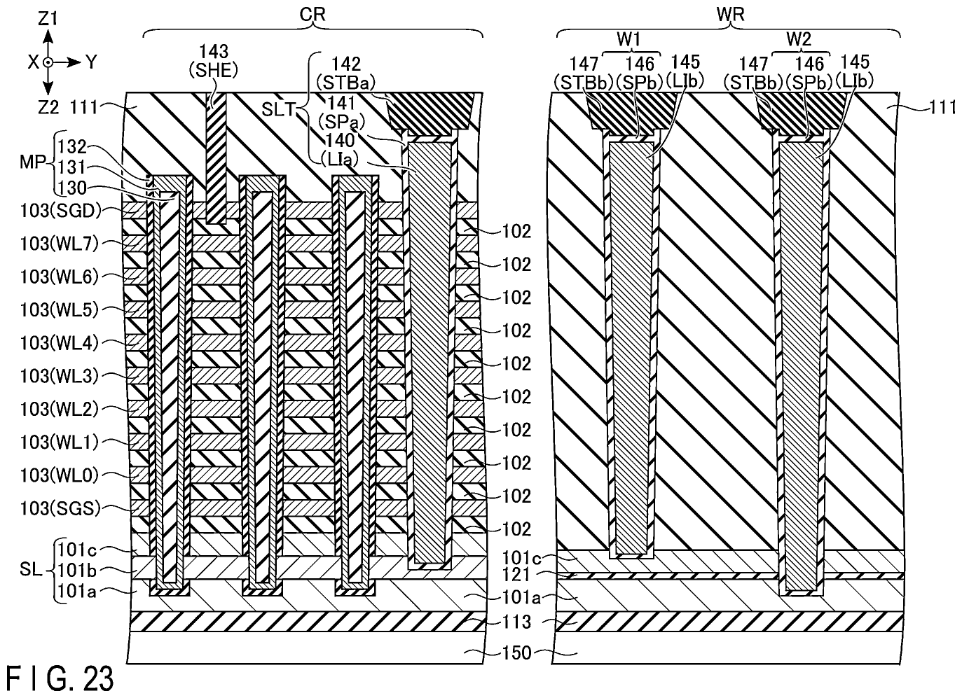

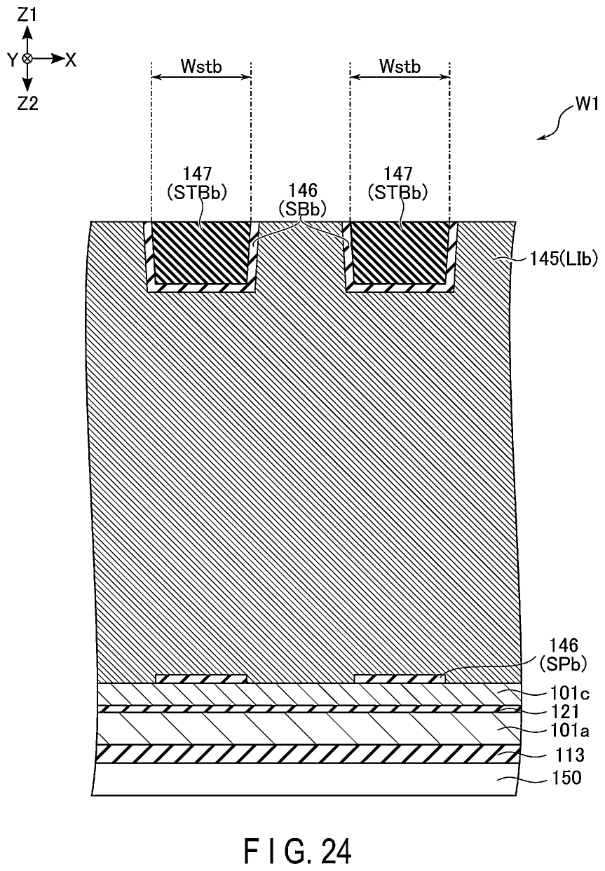

As shown in FIGS. 23 and 24, the wall structures W are each formed through replacement of the sacrificial member 156 with spacers SPb and a contact LIb. More specifically, and in one example, wet etching is first performed to selectively remove the sacrificial member 156 so as to form a groove (not shown in the figures) corresponding to the wall structure W. An insulator 146 and a conductor 145 are then provided to fill this groove. The Z1 direction top of the conductor 145 is accordingly formed in such a shape that a dent portion having the length Wstb is repeated at intervals along the longitudinal direction.

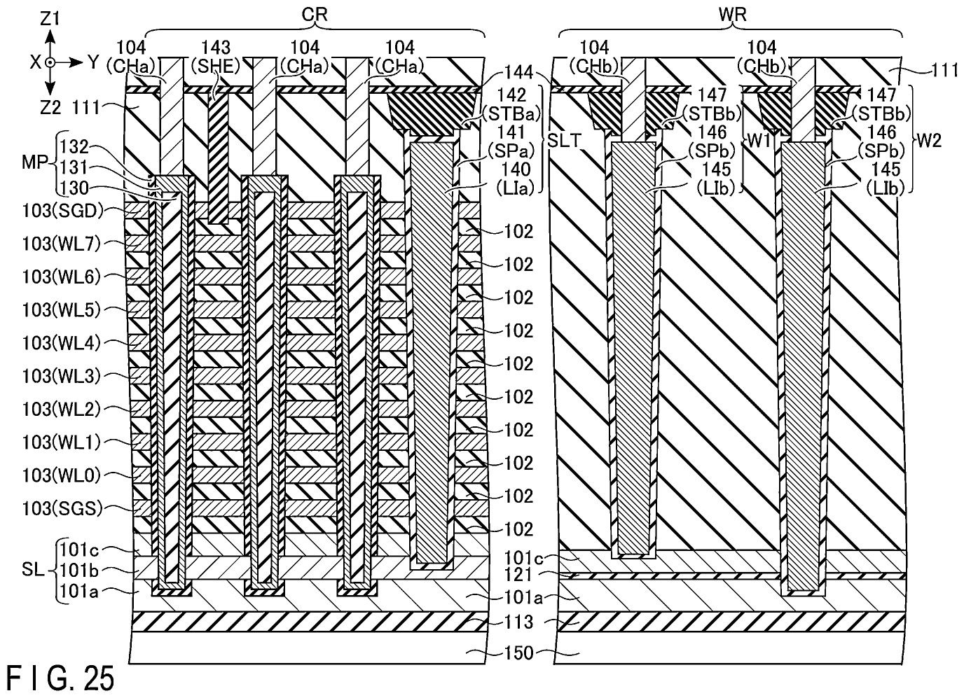

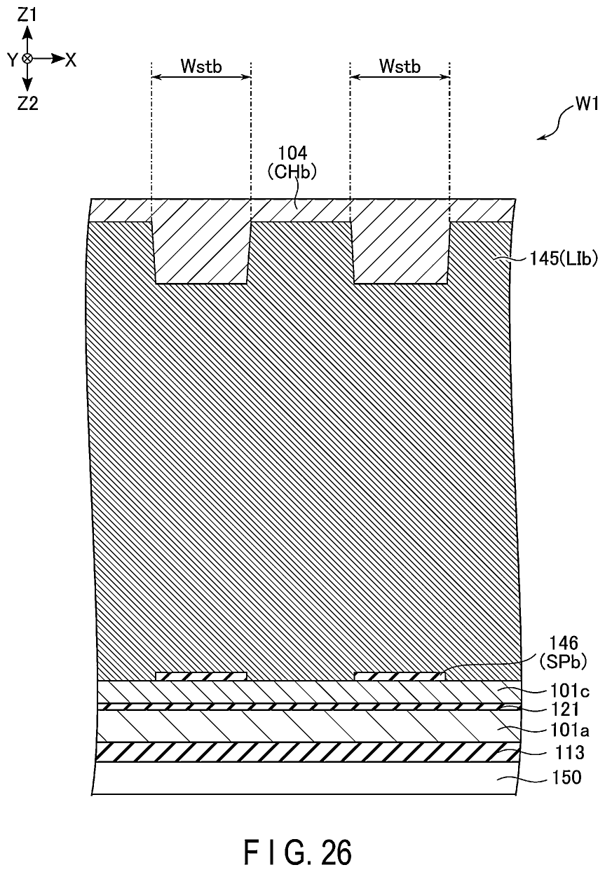

Subsequently, as shown in FIGS. 25 and 26, insulator layers 144 and 111 are provided in this order over the entire area. Thereafter, contacts CHa electrically coupled to the respective semiconductor films 131 in the memory pillars MP, and contacts CHb electrically coupled to the respective conductors 145 in the wall structures W are formed all together.

More specifically, holes (not shown in the figures) corresponding to the contacts CHa and grooves (not shown in the figures) corresponding to the contacts CHb are concurrently formed first. Here, the insulator layer 144 functions as a stopper film for adjusting the depths of the holes corresponding to the contacts CHa and the grooves corresponding to the contacts CHb. At the bottom surface of each hole corresponding to the contact CHa, the semiconductor film 131 formed in the memory pillar MP is exposed. At the bottom surface of each groove corresponding to the contact CHb, the conductor 145 formed in the wall structure W is exposed. Note that the bottom surface of the groove corresponding to the contact CHb reaches the conductor 145 irrespective of the presence or absence of the bridge member STBb. As such, the groove corresponding to the contact CHb has a dent and rise profile along the longitudinal direction of the wall structure W, in which the portion penetrating the bridge member STBb has a greater depth than the portion not penetrating the bridge member STBb.

Subsequently, the holes corresponding to the contacts CHa and the grooves corresponding to the contacts CHb are filled with conductors 104. The contacts CHa and CHb are thus formed. Therefore, the contacting interface between the conductor 104 and the conductor 145 has a dent and rise profile along the longitudinal direction of the wall structure W, following the profile of the groove corresponding to the contact CHb.

Thereafter, the remaining portions of the memory chip 100 are formed. While illustration is omitted, formation of the circuit chip 200 may proceed in parallel with the formation of the memory chip 100. The memory chip 100 and the circuit chip 200 are bonded to each other such that the electrodes 110 are positioned to contact the respective electrodes 211.

After the bonding process, the semiconductor substrate 150 of the memory chip 100 is taken away. Then, structure formation is conducted on a more Z2 direction side than the insulator layer 111 of the memory chip 100.

The memory device 3 is thus formed.

### 1.3 Effects of First Embodiment

In the course of forming the wall structures W1 to W6, grooves corresponding to the wall structures W1, W4, and W6 are provided together with the grooves corresponding to the wall structures W2, W3, and W5, and accordingly, it is guaranteed that the grooves corresponding to the wall structures W2, W3, and W5 each reach the semiconductor layer 101c. On the other hand, the depths of the grooves corresponding to the wall structures W1, W4, and W6 are not particularly guaranteed, and thus, these depths could vary from the depths of the grooves corresponding to the wall structures W2, W3, and W5. This may cause a situation where a shallow groove is filled up faster as compared to deeper grooves during the filling of the grooves corresponding to the wall structures W1 to W6 with the contacts LIb, which may create a stress exerted over the inter-groove structures in the width direction crossing the longitudinal direction of the grooves. This stress is not preferred as it can deform the wall structures W2, W3, and W5 in the width direction.

According to the first embodiment, the contacts LIb of the respective wall structures W1 to W6 each have, at the Z1 direction end, a dent and rise profile in the longitudinal direction. Such a dent and rise profile is formed by providing the multiple bridge members STBb. Each bridge member STBb is provided at the Z1 direction end in such a form as to bridge across the contact LIb in the width direction and to connect together the regions which are, in the Z direction perspective, inside and outside the contact LIb. The bridge members STBb are formed prior to the contact LIb filling the corresponding groove. With the bridge members STBb, therefore, occurrence of deformation of the wall structures W2, W3, and W5 due to the width direction stress can be avoided or prevented. Consequently, improved yields of the memory devices 3 can be realized.

### 2. Second Embodiment

Next, a memory device according to a second embodiment will be described. The second embodiment differs from the first embodiment in that the bridge members STBb are not formed in the wall structures W2, W3, and W5. The description will basically concentrate on aspects of the configurations and the manufacturing method that differ from the first embodiment. Aspects of the configuration and the manufacturing method that are common to the first embodiment will be omitted as appropriate.

### 2.1 Wall Structures in Wall Region and Outer Peripheral Region

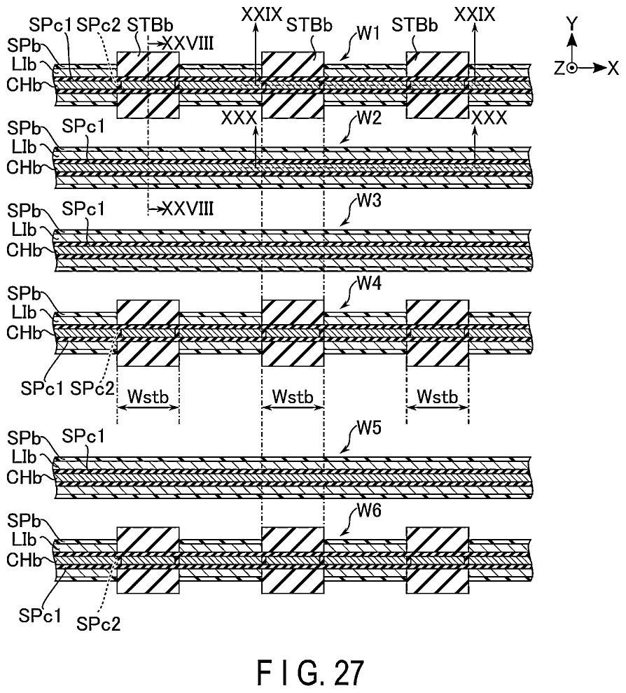

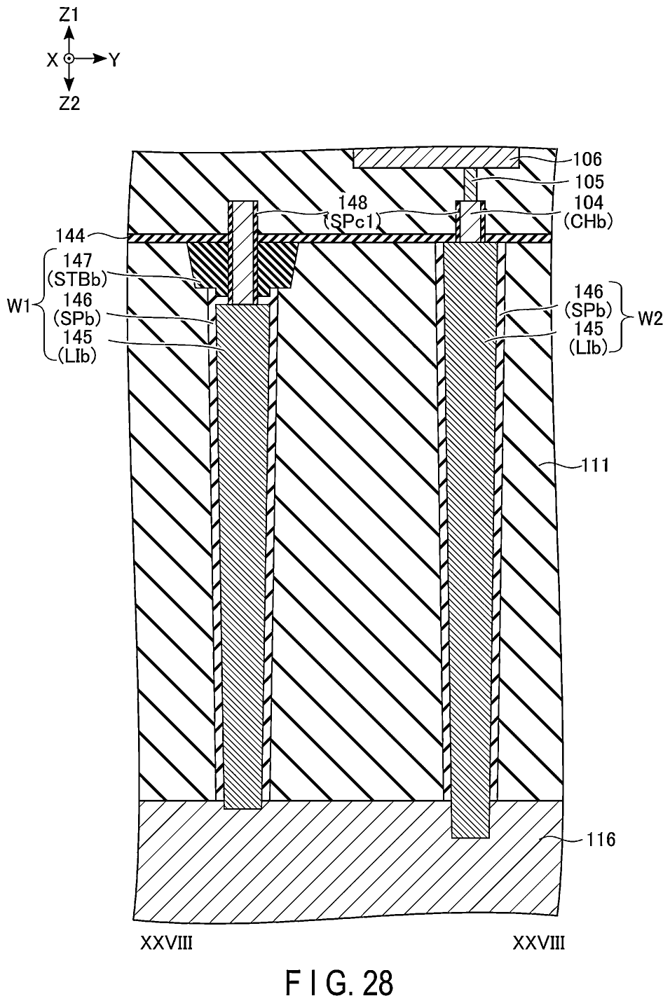

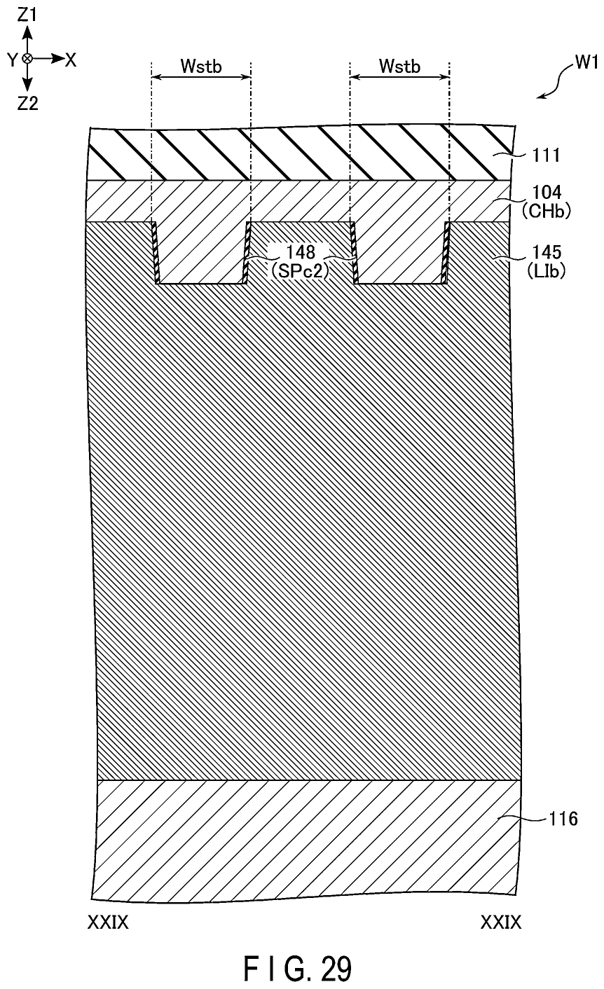

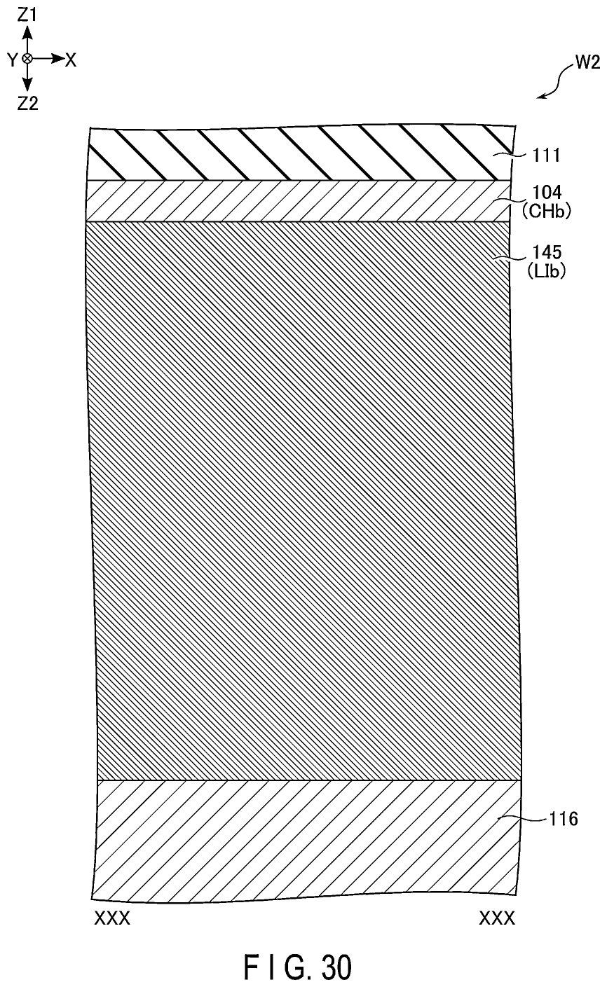

FIG. 27 is a plan view showing an exemplary planar layout of the wall region and the outer peripheral region in the memory device according to the second embodiment. FIG. 28 is a sectional view taken along the line XXVIII-XXVIII in FIG. 27 and shows an exemplary sectional structure of the wall region in the memory device according to the second embodiment. FIG. 29 is a sectional view taken along the line XXIX-XXIX in FIG. 27 and shows an exemplary sectional structure of the wall region in the memory device according to the second embodiment. FIG. 30 is a sectional view taken along the line XXX-XXX in FIG. 27 and shows an exemplary sectional structure of the wall region in the memory device according to the second embodiment. FIGS. 27, 28, and 29 correspond to respective FIGS. 11, 12, and 14 referred to for the first embodiment.

According to the second embodiment, each of the wall structures W1, W4, and W6 includes the contact LIb, the spacers SPb, and the multiple bridge members STBb. Thus, the Z1 direction ends of the wall structures W1, W4, and W6 each have the dent and rise profile in the longitudinal direction. On the other hand, each of the wall structures W2, W3, and W5, while including the contact LIb and the spacers SPb, does not include the multiple bridge members STBb. AS such, the Z1 direction ends of the wall structures W2, W3, and W5 each have a flat profile in the longitudinal direction.

Also according to the second embodiment, insulators 148 which function as spacers SPc are provided on the respective side surfaces of the contact CHb. Each insulator 148 contains, for example, silicon oxide. The side surfaces of the contact CHb for each of the wall structures W1, W4, and W6 include portions extending along the longitudinal direction of the wall structures W1, W4, and W6, and also portions extending along the width direction of the wall structures W1, W4, and W6. Among the side surfaces of the contact CHb in each of the wall structures W1, W4, and W6, the portions extending along the width direction are located in the dent portions of the contact LIb. Thus, in each of the wall structures W1, W4, and W6, while the conductors 145 and 104 are, in the Z direction perspective, in contact with each other in the Z direction at two different Z direction positions or levels alternately along their longitudinal direction, they are not in contact with each other via the lateral faces in the dent and rise profile since the insulator 148 is interposed between the conductors 145 and 104 there.

In contrast, the side surfaces of the contact CHb for each of the wall structures W2, W3, and W5 include portions extending along the longitudinal direction of the wall structures W2, W3, and W5, but do not include portions extending along the width direction of the wall structures W2, W3, and W5. Thus, in each of the wall structures W2, W3, and W5, the conductors 145 and 104 are, in the Z direction perspective, in contact with each other in the Z direction at substantially a constant Z direction position or level along their longitudinal direction.

In FIGS. 27, 28, and 29, the spacers SPc that cover the portions extending along the longitudinal direction among the side surface portions of the contact CHb for each of the wall structures W1 to W6 are denoted as “SPc1”. Also, the spacers SPc that cover the portions extending along the width direction among the side surface portions of the contact CHb for each of the wall structures W1, W4, and W6 are denoted as “SPc2”. The spacers SPc2 connect together the regions inside and outside the corresponding wall structure W without interposing this wall structure W.

Note that the contacts CHb are formed concurrently with the contacts CHa through the same process as discussed above. Accordingly, insulators functioning as spacers are also formed on the side surfaces of the contacts CHa together with the formation of the spacers SPC on the side surfaces of the contacts CHb (illustrations are omitted).

### 2.2 Effects of Second Embodiment

The occurrence of stress which can deform the wall structures W2, W3, and W5 in the width direction is mainly attributable to the grooves corresponding to the wall structures W1, W4, and W6 of which depths are not guaranteed.

According to the second embodiment, the multiple bridge members STBb are provided in the wall structures W1, W4, and W6. This enables the suppression or prevention of the occurrence of stress which would cause the width direction deformation of the wall structures W2, W3, and W5, without the multiple bridge members STBb provided in the wall structures W2, W3, and W5. Accordingly, the contacts LIb of the respective wall structures W2, W3, and W5 can each have the Z1 direction end having a flat profile in the longitudinal direction. The wall structures W2, W3, and W5 are thus formed into simpler structures, and consequently, a drop in yields due to complex structures can be avoided or prevented.

In addition, since the wall structures W2, W3, and W5 are not provided with the bridge members STBb, the contacts CHb for the wall structures W2, W3, and W5 do not include, as the side surface portion, a portion extending along the width direction of the wall structures W2, W3, and W5. This obviates the occurrence of an event where the spacers SPb provided on the side surfaces of the contacts CHb invade through each of the wall structures W2, W3, and W5 in the width direction. Therefore, a function of the wall structures W2, W3, and W5, i.e., protecting the core region CR and the peripheral circuit region PR against external influences, can be prevented from degrading.

### 3. Modifications, Etc.

The first and second embodiments described above may adopt various modifications.

### 3.1 First Modification

The first and second embodiments have assumed that each of the wall structures W1 to W6 is provided with the corresponding contact CHb, but the structures are not limited to such a form. As one example, the contact CHb for each of the wall structures W1, W4, W5, and W6 may be omitted.

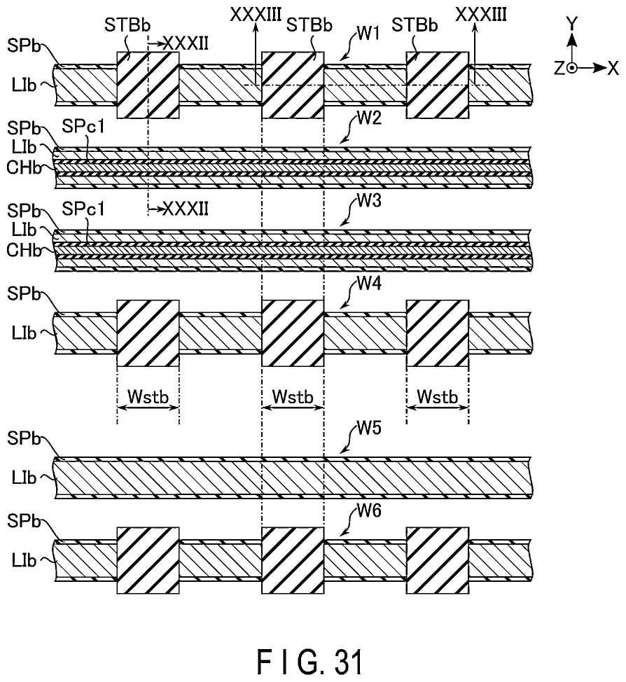

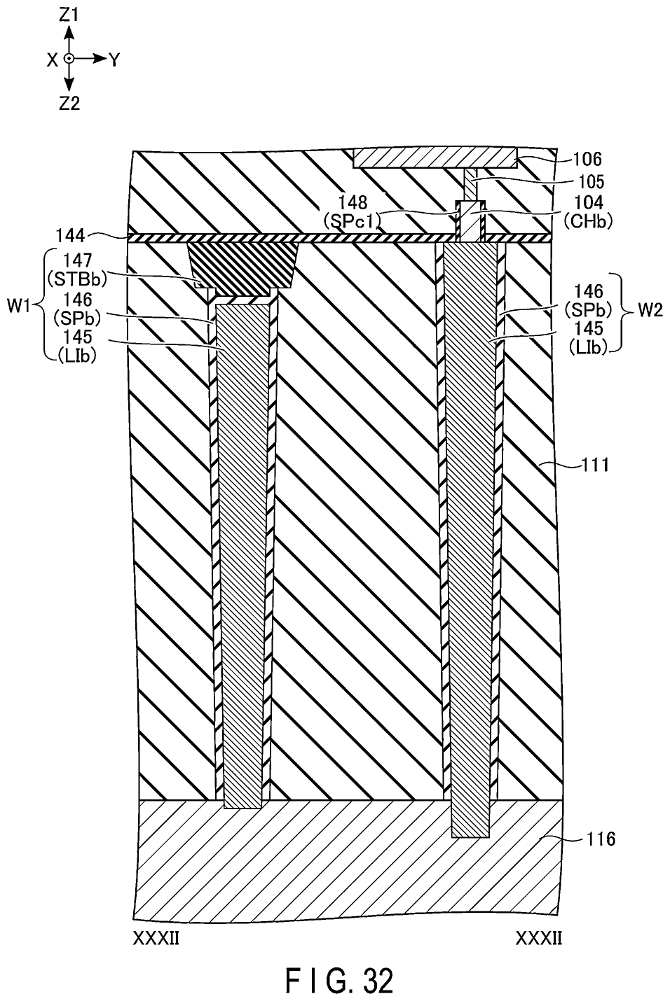

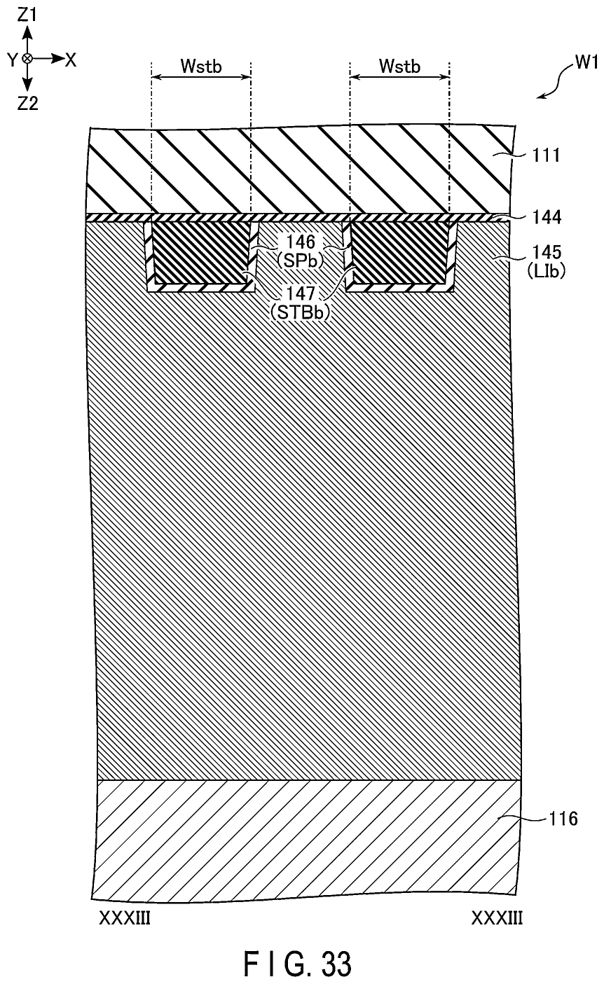

FIG. 31 is a plan view showing an exemplary planar layout of a wall region and an outer peripheral region in a memory device according to a first modification. FIG. 32 is a sectional view taken along the line XXXII-XXXII in FIG. 31 and shows an exemplary sectional structure of the wall region in the memory device according to the first modification. FIG. 33 is a sectional view taken along the line XXXIII-XXXIII in FIG. 31 and shows an exemplary sectional structure of the wall region in the memory device according to the first modification. FIGS. 31, 32, and 33 correspond to respective FIGS. 27, 28, and 29 referred to for the second embodiment.

As shown in FIGS. 31, 32, and 33, among the wall structures W1 to W6, the wall structures W1, W4, W5, and W6, excluding the wall structures W2 and W3, may be formed without the contact CHb.

In this case, the bridge members STBb in each of the wall structures W1, W4, and W6 are not subjected to partial removal, but remain there. Accordingly, the dent portions formed in the conductor 145 in each of the wall structures W1, W4, and W6 are filled with the bridge members STBb.

### 3.2 Second Modification

The second embodiment has assumed that the bridge members STBb are formed in the wall structures W1, W4, and W6, but this does not pose a limitation.

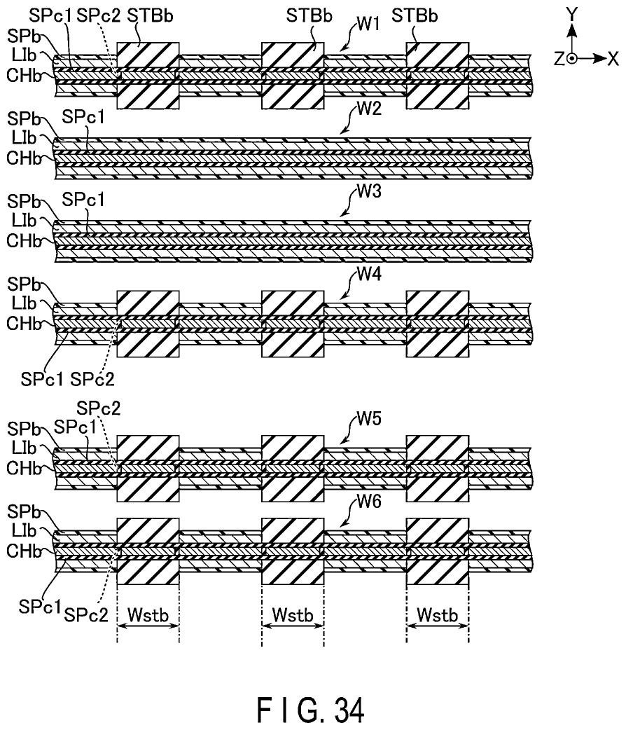

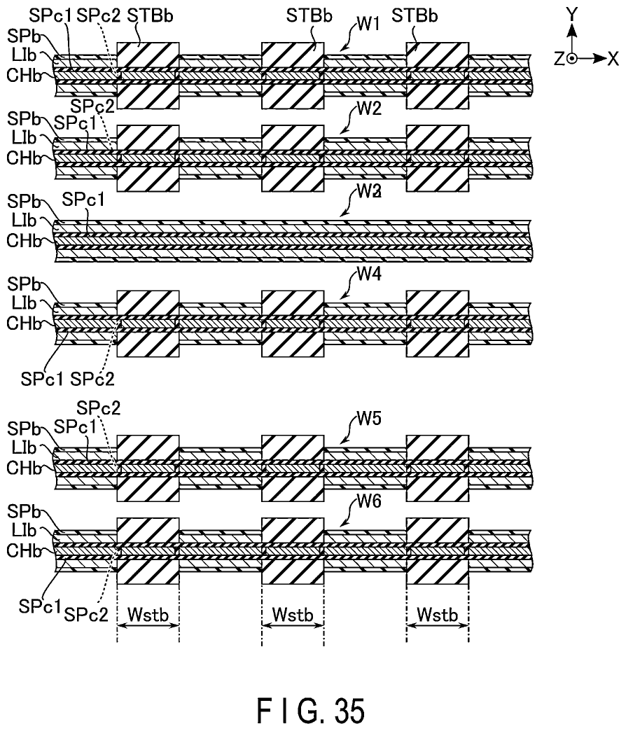

FIG. 34 is a plan view showing a first exemplary planar layout of the wall region and the outer peripheral region in a memory device according to a second modification. FIG. 35 is a plan view showing a second exemplary planar layout of the wall region and the outer peripheral region in the memory device according to the second modification. FIGS. 34 and 35 correspond to FIG. 27 referred to for the second embodiment.

As shown in FIG. 34, the bridge members STBb may be provided in the wall structures W1, W4, W5, and W6. As shown in FIG. 35, the bridge members STBb may be provided in the wall structures W1, W2, W4, W5, and W6. While illustration is omitted, the bridge members STBb may also be provided in the wall structures W1, W3, W4, W5, and W6.

As explained above, the bridge members STBb serve to prevent deformation of the wall structures W which could occur due to a width direction stress during the process of forming the wall structures W. As such, the presence of more wall structures W that include the formed bridge members STBb may further stabilize the structure of the memory chip 100 during the formation of the wall structures W. Meanwhile, if the contact CHb having the spacers SPC covering its side surfaces is formed in the wall structure W that includes the bridge members STBb, the regions inside and outside the wall structure W are connected to each other via the spacers SPc2. Such spacers SPc2 could degrade the function of the wall structure W protecting the core region CR and the peripheral circuit region PR, and therefore are not preferable. Thus, for adopting the configuration in which the contact CHb having the spacers SPc covering its side surfaces is formed in the wall structure W that includes the bridge members STBb, it is not preferred that all the wall structures W have been provided with the bridge members STBb. In particular, the wall structures W2 and W3 are constituted to protect the core region CR and the peripheral circuit region PR in cooperation with the conductors 104, 105, 107, 109, 204, 206, 208, and 210, the interconnect layers 106, 108, 205, 207, and 209, and the electrodes 110 and 211; that is, the wall structures W2 and W3 provide a high ability to protect the core region CR and the peripheral circuit region PR. Therefore, providing the bridge members STBb in both the wall structures W2 and W3 is not preferred.

According to the second modification, the bridge members STBb are provided in the wall structures W excluding at least one of the wall structures W2 and W3 among the wall structures W1 to W6. This can realize an enhanced stabilization in the structure of the memory chip 100 during the process of forming the wall structures W, while securing the function of the wall structures W protecting the core region CR and the peripheral circuit region PR.

### 3.3 Third Modification

The first and second embodiments have assumed that the Z2 direction end of the wall structure W1 reaches the interconnect layer 116, but this does not pose a limitation.

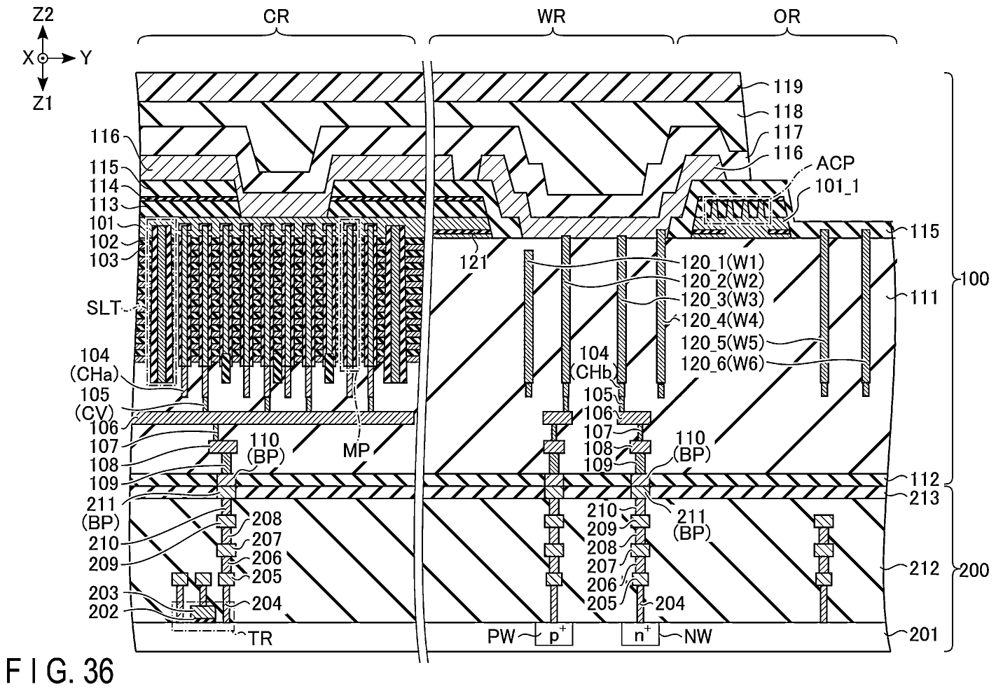

FIG. 36 is a sectional view showing an exemplary sectional structure of a memory device according to a third modification. FIG. 36 corresponds to FIG. 5 referred to for the first embodiment. As shown in FIG. 36, the Z2 direction end of the wall structure W1 may not reach the interconnect layer 116. In this case, the wall structure W1 may cross the extension of at least one interconnect layer 103 on the Z1 direction side among the multiple interconnect layers 103.

In the third modification as compared to the foregoing examples, the difference in Z direction length between the wall structure W1 and the wall structure W2 is large, and thus, the stress acting to deform the wall structure W2 in the width direction could become large. However, with the presence of the bridge members STBb, occurrence of the deformation of the wall structures W2 due to this stress can be avoided or prevented.

### 3.4 Others

The second embodiment has assumed configurations or structures with the spacers SPc, but the spacers SPC may be omitted. In this case, different spacers may be provided to cover the side surfaces of the contact CHa connected to the memory pillar MP, or such spacers may be omitted as the spacers SPc.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device comprising:
a plurality of first conductor layers arranged apart from each other in a first direction;
a memory pillar extending in the first direction and including a portion crossing a respective one of the first conductor layers, the portion functioning as a memory cell; and
a first conductor member surrounding, in a first direction perspective, the first conductor layers and the memory pillar, the first conductor member crossing an extension of at least one of the first conductor layers,
wherein the first conductor member includes a first direction first end having, in the first direction perspective, a dent and rise profile in a longitudinal direction of the first conductor member.

2. The memory device according to claim 1, further comprising:
a second conductor member surrounding, in the first direction perspective, the first conductor layers and the memory pillar, the second conductor member contacting the first direction first end of the first conductor member; and
a first insulator member covering a side surface of the second conductor member,
wherein the first insulator member connects a first region and a second region to each other without interposing the first conductor member and the second conductor member, the first region being, in the first direction perspective, on a side of the first conductor layers and the memory pillar with respect to the first conductor member and the second conductor member, the second region being on an opposite side to the first region.

3. The memory device according to claim 1, further comprising a third conductor member surrounding, in the first direction perspective, the first conductor layers and the memory pillar and apart from the first conductor member, the third conductor member crossing respective extensions of the first conductor layers,
wherein the third conductor member includes a first direction first end having, in the first direction perspective, a flat profile in a longitudinal direction of the third conductor member, the first direction first end of the third conductor member being on a same side in the first direction as the first direction first end of the first conductor member.

4. The memory device according to claim 1, further comprising a third conductor member surrounding, in the first direction perspective, the first conductor layers and the memory pillar and apart from the first conductor member, the third conductor member crossing respective extensions of the first conductor layers,
wherein the third conductor member includes a first direction first end having, in the first direction perspective, a dent and rise profile in a longitudinal direction of the third conductor member, the first direction first end of the third conductor member being on a same side in the first direction as the first direction first end of the first conductor member.

5. The memory device according to claim 3, further comprising a fourth conductor member surrounding, in the first direction perspective, the first conductor layers and the memory pillar, the fourth conductor member contacting the first direction first end of the third conductor member.

6. The memory device according to claim 3, further comprising:
a first electrode electrically coupled to the third conductor member, the first conductor layers, the memory pillar, the first conductor member, the third conductor member, and the first electrode being included in a first chip; and
a second electrode in contact with the first electrode, he second electrode being included in a second chip provided with a substrate and electrically coupled to the second chip.

7. The memory device according to claim 6, wherein the first conductor member is electrically isolated from the second chip.

8. The memory device according to claim 3, further comprising a second conductor layer contacting a first direction second end of the third conductor member which is opposite the first direction first end of the third conductor member.

9. The memory device according to claim 1, further comprising a first member extending in the first direction and a second direction crossing the first direction, the first member splitting the first conductor layers,
wherein the first member includes a first direction first end having a dent and rise profile in the second direction, the first direction first end of the first member being on a same side in the first direction as the first direction first end of the first conductor member.

10. The memory device according to claim 9, wherein the first member includes
a fifth conductor member extending in the first direction and the second direction, and
a second insulator member between the first conductor layers and the fifth conductor member.

11. A memory device comprising:
a plurality of first conductor layers arranged apart from each other in a first direction;
a memory pillar extending in the first direction and including a portion crossing a respective one of the first conductor layers, the portion functioning as a memory cell;
a first conductor member surrounding, in a first direction perspective, the first conductor layers and the memory pillar, the first conductor member crossing an extension of at least one of the first conductor layers; and
a second conductor member surrounding, in the first direction perspective, the first conductor layers and the memory pillar, the second conductor member contacting a first direction first end of the first conductor member,
wherein, in the first direction perspective, the first conductor member and the second conductor member are in contact with each other in the first direction at two positions alternately along a longitudinal direction of the first conductor member and the second conductor member, the two positions differing from each other in the first direction.

12. The memory device according to claim 11, wherein the first conductor member and the second conductor member are further in contact with each other between the two positions in the first direction and in the longitudinal direction of the first conductor member and the second conductor member.

13. The memory device according to claim 11, further comprising a first insulator member covering a side surface of the second conductor member,
wherein the first insulator member is interposed between the first conductor member and the second conductor member, and located between the two positions in the first direction.

14. The memory device according to claim 13, wherein the first insulator member connects a first region and a second region to each other without interposing the first conductor member and the second conductor member, the first region being, in the first direction perspective, on a side of the first conductor layers and the memory pillar with respect to the first conductor member and the second conductor member, the second region being on an opposite side to the first region.

15. The memory device according to claim 11, further comprising:
a third conductor member surrounding, in the first direction perspective, the first conductor layers and the memory pillar and apart from the first conductor member, the third conductor member crossing respective extensions of the first conductor layers; and
a fourth conductor member surrounding, in the first direction perspective, the first conductor layers and the memory pillar, the fourth conductor member contacting a first direction first end of the third conductor on a same side in the first direction where the first direction first end of the first conductor member and the second conductor member are in contact with each other,
wherein, in the first direction perspective, the third conductor member and the fourth conductor member are in contact with each other in the first direction at substantially a constant first direction position along a longitudinal direction of the third conductor member and the fourth conductor member.

16. The memory device according to claim 12, further comprising:
a third conductor member surrounding, in the first direction perspective, the first conductor layers and the memory pillar and apart from the first conductor member, the third conductor member crossing respective extensions of the first conductor layers; and
a fourth conductor member surrounding, in the first direction perspective, the first conductor layers and the memory pillar, the fourth conductor member contacting a first direction first end of the third conductor on a same side in the first direction where the first direction first end of the first conductor member and the second conductor member are in contact with each other,
wherein, in the first direction perspective, the third conductor member and the fourth conductor member are in contact with each other in the first direction at two positions alternately along a longitudinal direction of the third conductor member and the fourth conductor member, the two positions differing from each other in the first direction.

17. The memory device according to claim 15, further comprising:
a first electrode electrically coupled to the fourth conductor member, the first conductor layers, the memory pillar, the first conductor member, the second conductor member, the third conductor member, the fourth conductor member, and the first electrode being included in a first chip; and
a second electrode in contact with the first electrode, the second electrode being included in a second chip provided with a substrate and electrically coupled to the second chip.

18. The memory device according to claim 17, wherein the first conductor member and the second conductor member are electrically isolated from the second chip.

19. The memory device according to claim 15, further comprising a second conductor layer contacting a first direction second end of the third conductor member which is opposite the first direction first end of the third conductor member.

20. The memory device according to claim 11, wherein
the first conductor member extends in the first direction and crosses respective extensions of the first conductor layers, and
the second conductor member does not cross the respective extensions of the first conductor layers.
